(19) United States
(12) Patent Application Publication
(10) Pub. No.: US 2025/0004369 A1
(43) Pub. Date: Jan. 2, 2025

(54) PHOTOSENSITIVE RESIN COMPOSITION, PHOTOSENSITIVE ELEMENT, AND LAMINATE PRODUCTION METHOD

(71) Applicant: Resonac Corporation, Tokyo (JP)

(72) Inventors: Shiho TANAKA, Tokyo (JP); Keishi ONO, Tokyo (JP)

(21) Appl. No.: 18/703,643

(22) PCT Filed: Oct. 24, 2022
(86) PCT No.: PCT/JP2022/039545

§ 371 Date: Apr. 22, 2024

(30) Foreign Application Priority Data
Oct. 26, 2021 (WO) PCT/JP2021/039426

(51) Int. Cl. G03F 7/033; G03F 7/031

(52) U.S. Cl. CPC G03F 7/033; G03F 7/031

(57) ABSTRACT

A photosensitive resin composition containing (A) a binder polymer, (B) a photopolymerizable compound, and (C) a photopolymerization initiator, in which the component (B) includes a polyfunctional compound having three or more ethylenically unsaturated bonds, and in a case where development is performed after exposing a layer (thickness 25 μm) of the photosensitive resin composition at a wavelength of 405 nm using a 41-step tablet (concentration region 0.00 to 2.00, concentration step 0.05, tablet size 20 mm×187 mm, each step size 3 mm× 12 mm), an exposure dose providing 15 steps as the number of remaining steps is 30 mJ/cm² or less.

### TECHNICAL FIELD

The present disclosure relates to a photosensitive resin composition, a photosensitive element, a method for producing a laminate, and the like.

### BACKGROUND ART

In the production of laminates that can be used as wiring boards and the like, in a state where resist patterns are formed on a metal layer, an exposed area of the metal layer (a part not covered with the resist patterns) is removed by etching, the resist patterns are then peeled off, and thus desired wirings can be formed. The resist patterns can be formed by exposing and developing a layer of a photosensitive resin composition. As the photosensitive resin composition, various compositions have been investigated. For example, Patent Literature 1 below describes a photosensitive resin composition containing a binder polymer, a photopolymerizable compound, and a specific photopolymerization initiator.

### CITATION LIST

### Patent Literature

Patent Literature 1: Japanese Unexamined Patent Publication No. 2019-028398

### SUMMARY OF INVENTION

### Technical Problem

For a photosensitive resin composition for forming a cured product pattern that can be used as a resist pattern, it is required to have excellent sensitivity from the viewpoint of improving productivity by shortening a takt time during exposure, and the like. Furthermore, for such a photosensitive resin composition, it is required that a cured product of the photosensitive resin composition is not peeled off when the cured product comes into contact with an etching solution used in etching for removing an exposed area of the metal layer. However, in a photosensitive resin composition having excellent sensitivity, it is not easy to obtain a cured product having excellent etching solution resistance.

An object of an aspect of the present disclosure is to provide a photosensitive resin composition having excellent sensitivity and capable of obtaining a cured product having excellent etching solution resistance. An object of another aspect of the present disclosure is to provide a photosensitive element using this photosensitive resin composition. An object of still another aspect of the present disclosure is to provide a method for producing a laminate using the above-described photosensitive resin composition or photosensitive element.

### Solution to Problem

In reaction to such problems, the present inventors have found that a resin composition from which a cured product having excellent etching solution resistance is obtainable does not necessarily have excellent sensitivity, focused on use of a photopolymerizable compound having three or more ethylenically unsaturated bonds, and found that the above-described problems cannot be solved only by using the photopolymerizable compound having three or more ethylenically unsaturated bonds. On the other hand, the present inventors have found that the above-described problems can be solved by using a photopolymerizable compound having three or more ethylenically unsaturated bonds in a photosensitive resin composition (photosensitive resin composition having excellent sensitivity) in which an exposure dose providing 15 steps as the number of remaining steps is 30 mJ/cm² or less in a case where development is performed after exposing a layer (thickness 25 μm) of the photosensitive resin composition at a wavelength of 405 nm using a 41-step tablet (concentration region 0.00 to 2.00, concentration step 0.05, tablet size 20 mm×187 mm, each step size 3 mm×12 mm).

Furthermore, the present inventors have found that the above-described problems can be solved by using a specific photopolymerizable compound having three or more ethylenically unsaturated bonds, 2,2-bis(4-((meth)acryloxypentaethoxy)phenyl)propane, and an acridine compound in combination.

The present disclosure relates to the following [1] to [19] and the like in several aspects.
[1] A photosensitive resin composition containing (A) a binder polymer, (B) a photopolymerizable compound, and (C) a photopolymerization initiator, in which the component (B) includes a polyfunctional compound having three or more ethylenically unsaturated bonds, and in a case where development is performed after exposing a layer (thickness 25 μm) of the photosensitive resin composition at a wavelength of 405 nm using a 41-step tablet (concentration region 0.00 to 2.00, concentration step 0.05, tablet size 20 mm×187 mm, each step size 3 mm×12 mm), an exposure dose providing 15 steps as the number of remaining steps is 30 mJ/cm² or less.
[2] The photosensitive resin composition described in [1], in which the component (B) includes a polyfunctional compound having three ethylenically unsaturated bonds.
[3] The photosensitive resin composition described in [1], in which the component (B) includes a polyfunctional compound having six ethylenically unsaturated bonds.
[4] The photosensitive resin composition described in [1], in which the component (B) includes a polyfunctional compound having three ethylenically unsaturated bonds and a polyfunctional compound having six ethylenically unsaturated bonds.
[5] The photosensitive resin composition described in any one of [1] to [4], in which the component (C) includes an acridine compound.
[6] The photosensitive resin composition described in any one of [1] to [4], in which the component (C) includes an acridine compound and a N-phenylglycine compound.
[7] The photosensitive resin composition described in any one of [1] to [6], in which a content of the polyfunctional compound is 1 to 10% by mass on the basis of the total amount of the photosensitive resin composition.
[8] The photosensitive resin composition described in any one of [1] to [7], in which a content of the polyfunctional compound is 3 to 30% by mass on the basis of the total amount of the component (B).
[9] The photosensitive resin composition described in any one of [1] to [8], in which the component (B) further includes a bisphenol A-type (meth)acrylic acid compound.
[10] A photosensitive resin composition containing: (A) a binder polymer; (B) a photopolymerizable compound; and (C) a photopolymerization initiator, in which the component (B) includes at least one selected from the group consisting of trimethylolpropane tri(meth)acrylate, alkylene oxide-modified trimethylolpropane tri(meth)acrylate, dipentaerythritol hexa(meth)acrylate, and alkylene oxide-modified dipentaerythritol hexa(meth)acrylate, and 2,2-bis(4-((meth)acryloxypentaethoxy)phenyl)propane, and the component (C) includes an acridine compound.
[11] The photosensitive resin composition described in [10], in which the component (B) includes alkylene oxide-modified trimethylolpropane tri(meth)acrylate.
[12] The photosensitive resin composition described in any one of [1] to [11], in which a content of the component (B) is 30 to 60 parts by mass with respect to a total of 100 parts by mass of the component (A) and the component (B).
[13] The photosensitive resin composition described in any one of [1] to [12], in which the component (A) has a (meth)acrylic acid and a styrene compound as monomer units.
[14] The photosensitive resin composition described in any one of [1] to [13], in which the component (A) has a styrene compound as a monomer unit, and a content of the monomer unit of the styrene compound is 1 to 30% by mass on the basis of the total amount of monomer units constituting the component (A).
[15] The photosensitive resin composition described in any one of [1] to [14], in which a weight average molecular weight of the component (A) is 3.0×10⁴ to 5.0×10⁴.
[16] The photosensitive resin composition described in any one of [1] to [15], further containing tribromomethyl phenyl sulfone.
[17] The photosensitive resin composition described in any one of [1] to [16], which is in a film form.
[18] A photosensitive element having: a support; and a photosensitive resin layer disposed on the support, in which the photosensitive resin layer is a layer of the photosensitive resin composition described in any one of [1] to [17].
[19] A method for producing a laminate, the method including: a step of disposing a layer of the photosensitive resin composition on a base material by using the photosensitive resin composition described in any one of [1] to [17] or the photosensitive element described in [18]; a step of photo-curing a part of the layer of the photosensitive resin composition; and a step of removing at least a part of an uncured area of the layer of the photosensitive resin composition to form a cured product pattern.

### Advantageous Effects of Invention

According to an aspect of the present disclosure, it is possible to provide a photosensitive resin composition having excellent sensitivity and capable of obtaining a cured product having excellent etching solution resistance. According to another aspect of the present disclosure, it is possible to provide a photosensitive element using this photosensitive resin composition. According to still another aspect of the present disclosure, it is possible to provide a method for producing a laminate using the above-described photosensitive resin composition or photosensitive element.

### BRIEF DESCRIPTION OF DRAWINGS

FIG. 1 is a schematic cross-sectional view illustrating an example of a photosensitive element.

### DESCRIPTION OF EMBODIMENTS

Hereinafter, embodiments of the present disclosure will be described in detail. However, the present disclosure is not limited to the following embodiments.

In the present specification, a numerical range that has been indicated by use of “to” indicates the range that includes the numerical values which are described before and after “to”, as the minimum value and the maximum value, respectively. The numerical range “A or more” means A and a range of more than A. The numerical range “A or less” means A and a range of less than A. In the numerical ranges that are described stepwise in the present specification, the upper limit value or the lower limit value of the numerical range of a certain stage can be arbitrarily combined with the upper limit value or the lower limit value of the numerical range of another stage. In a numerical range described in the present specification, the upper limit value or the lower limit value of the numerical range may be substituted by a value shown in Examples. “A or B” may include either one of A and B, and may also include both of A and B. Materials listed as examples in the present specification can be used singly or in combinations of two or more kinds, unless otherwise specified. When a plurality of substances corresponding to each component exist in the composition, the content of each component in the composition means the total amount of the plurality of substances that exist in the composition, unless otherwise specified. The term “layer” includes a structure having a shape which is formed on a part, in addition to a structure having a shape which is formed on the whole surface, when the layer has been observed as a plan view. The term “step” includes not only an independent step but also a step by which an intended action of the step is achieved, even though the step cannot be clearly distinguished from other steps. The term “(meth)acrylic acid” means at least one of acrylic acid and methacrylic acid corresponding thereto. The same applies to other analogous expressions such as “(meth)acrylate”. The content of the (meth)acrylic acid compound means the total amount of the acrylic acid compound and the methacrylic acid compound, and the same applies to other analogous expressions. The “alkyl group” may be linear, branched, or cyclic, unless otherwise specified. The term “EO-modified” means a compound having a polyoxyethylene group. The term “PO-modified” means a compound having a polyoxypropylene group. The term “EO/PO-modified” means a compound having a polyoxyethylene group and a (poly)oxypropylene group.

In the present specification, the solid content of a photosensitive resin composition refers to a non-volatile content of a photosensitive resin composition excluding substances that can volatilize (such as water and an organic solvent). That is, this solid content refers to a component remaining without volatile in drying of the photosensitive resin composition and also includes a component in a liquid, syrupy, waxy state, or the like at room temperature (25° C.).

### <Photosensitive Resin Composition>

A photosensitive resin composition of the present embodiment (including photosensitive resin compositions of a first embodiment and a second embodiment described below; the same applies hereinafter) contains (A) a binder polymer (component (A)), (B) a photopolymerizable compound (component (B)), and (C) a photopolymerization initiator (component (C)). In the photosensitive resin composition of the first embodiment, the component (B) includes a polyfunctional compound having three or more ethylenically unsaturated bonds, and in a case where development is performed after exposing a layer (thickness 25 μm) of the photosensitive resin composition at a wavelength of 405 nm using a 41-step tablet (concentration region 0.00 to 2.00, concentration step 0.05, tablet size 20 mm×187 mm, each step size 3 mm×12 mm), an exposure dose (hereinafter, sometimes referred to as “exposure dose a”) providing 15 steps as the number of remaining steps (residual step number; residual film number) is 30 mJ/cm² or less. In the photosensitive resin composition of the second embodiment, the component (B) includes at least one selected from the group consisting of trimethylolpropane tri(meth)acrylate, alkylene oxide-modified trimethylolpropane tri(meth)acrylate, dipentaerythritol hexa(meth)acrylate, and alkylene oxide-modified dipentaerythritol hexa(meth)acrylate, and 2,2-bis(4-((meth)acryloxypentaethoxy)phenyl)propane, and the component (C) includes an acridine compound.

The photosensitive resin composition of the present embodiment is a photosensitive resin composition having excellent sensitivity (small exposure dose) and can obtain a cured product having excellent etching solution resistance (etching chemical solution resistance), and for example, a cured product having excellent acid resistance with respect to an acidic liquid used for etching (particularly, an etching solution containing hydrochloric acid) can be obtained.

As for the photosensitive resin composition of the first embodiment, the present inventors have speculated factors for excellent etching solution resistance obtained in a cured product while obtaining excellent sensitivity as follows. However, the factors are not limited to the contents to be as follows.

That is, when an exposure dose providing 15 steps as the number of remaining steps is 30 mJ/cm² or less (exposure dose is small) in a case where a layer of the photosensitive resin composition is exposed and developed using a 41-step tablet, the number of active species generated from the photopolymerization initiator is small. In this case, in the photosensitive resin composition of the first embodiment, since the number of reaction points is increased by using the polyfunctional compound having three or more ethylenically unsaturated bonds, even when the number of the active species generated from the photopolymerization initiator is small, the molecular weight of the polymer formed by cross-linking in the layer of the photosensitive resin composition increases, so that high etching solution resistance is obtained. On the other hand, since the number of reaction points is small when the polyfunctional compound is not used in a case where the exposure dose is 30 mJ/cm² or less (exposure dose is small), the molecular weight of the polymer formed by cross-linking in the layer of the photosensitive resin composition is difficult to increase, so that high etching solution resistance is not obtained.

Furthermore, when an exposure dose providing 15 steps as the number of remaining steps is more than 30 mJ/cm² (exposure dose is large) in a case where a layer of the photosensitive resin composition is exposed and developed using a 41-step tablet, the number of active species generated from the photopolymerization initiator is large. In this case, since the number of reaction points is small but the number of the active species is large when the polyfunctional compound is not used, the molecular weight of the polymer formed by cross-linking in the layer of the photosensitive resin composition increases, so that high etching solution resistance is obtained in some cases. On the other hand, since the number of reaction points increases in a state where the number of the active species is large when the polyfunctional compound is used in a case where the exposure dose is more than 30 mJ/cm² (exposure dose is large), the molecular weight of the polymer formed by cross-linking in the layer of the photosensitive resin composition is difficult to increase, so that high etching solution resistance is not obtained.

A step tablet is a member in which light is shielded so that the optical density gradually increases. When the layer of the photosensitive resin composition is developed after exposing it in a state where the step tablet is disposed on the layer of the photosensitive resin composition, the number of steps in which the cured product of the photosensitive resin composition is peeled off changes according to the sensitivity of the photosensitive resin composition. In the first embodiment, a 41-step tablet (concentration region 0.00 to 2.00, concentration step 0.05, tablet size 20 mm×187 mm, each step size 3 mm×12 mm) is used. A translucent member such as a support of a photosensitive element may be disposed between the step tablet and the layer of the photosensitive resin composition.

The exposure and the development for evaluating the exposure dose a can be performed under atmospheric pressure. The exposure can be performed using a direct writing exposure machine and can be performed at room temperature (25° C.). The development can be performed by spray development and the pressure (spray pressure) may be 0.15 MPa. As a developing solution, a 1% by mass sodium carbonate aqueous solution set at 30° C. can be used. As a nozzle, a full-cone type nozzle can be used. A distance between an object to be treated and a nozzle tip may be 6 cm.

The exposure dose a is 30 mJ/cm² or less, and may be 28 mJ/cm² or less, 25 mJ/cm² or less, 23 mJ/cm² or less, 22 mJ/cm² or less, 21 mJ/cm² or less, 20 mJ/cm² or less, 19 mJ/cm² or less, 18 mJ/cm² or less, 17 mJ/cm² or less, 16 mJ/cm² or less, 15 mJ/cm² or less, or 14 mJ/cm² or less. The exposure dose a may be 5 mJ/cm² or more, 8 mJ/cm² or more, 10 mJ/cm² or more, 12 mJ/cm² or more, 14 mJ/cm² or more, 15 mJ/cm² or more, 16 mJ/cm² or more, 17 mJ/cm² or more, 18 mJ/cm² or more, 19 mJ/cm² or more, 20 mJ/cm² or more, 21 mJ/cm² or more, 22 mJ/cm² or more, 23 mJ/cm² or more, 25 mJ/cm² or more, or 28 mJ/cm² or more. From these viewpoints, the exposure dose a may be 5 to 30 mJ/cm². The exposure dose a can be adjusted by the type or content of a photopolymerization initiator, the type or content of a polymerization inhibitor, and the like.

As for the photosensitive resin composition of the second embodiment, the present inventors have speculated factors for excellent etching solution resistance obtained in a cured product while obtaining excellent sensitivity as follows. However, the factors are not limited to the contents to be as follows.

That is, in the photosensitive resin composition of the second embodiment, by using a specific photopolymerizable compound having three or more ethylenically unsaturated bonds, 2,2-bis(4-((meth)acryloxypentaethoxy)phenyl)propane, and an acridine compound in combination, an appropriate amount of active species is generated from the photopolymerization initiator so that excellent sensitivity can be obtained, and the number of reaction points can be sufficiently secured so that high etching solution resistance can be obtained.

The photosensitive resin composition of the present embodiment may be in a liquid form and may be a photosensitive film (film form). The photosensitive resin composition of the present embodiment has photo-curability and a cured product can be obtained by photo-curing this photosensitive resin composition. A cured product of the present embodiment is a cured product (photo-cured product) of the photosensitive resin composition of the present embodiment. The cured product of the present embodiment may have a patterned shape (cured product pattern), and may be a resist pattern. The shape of a cured product pattern that can be obtained by the photosensitive resin composition of the present embodiment is not particularly limited. The photosensitive resin composition of the present embodiment can be used for forming a resist pattern, the resist pattern may be removed after a treatment using this resist pattern (for example, an etching treatment of a member such as a metal layer disposed under the resist pattern).

The thickness of the layer of the photosensitive resin composition (for example, photosensitive film) or the cured product may be in the following range. The thickness of the layer of the photosensitive resin composition or the cured product may be 100 μm or less, 80 μm or less, 60 μm or less, 50 μm or less, 40 μm or less, 30 μm or less, or 25 μm or less, from the viewpoint of easily obtaining excellent etching solution resistance in the cured product. The thickness of the layer of the photosensitive resin composition or the cured product may be 1 μm or more, 3 μm or more, 5 μm or more, 8 μm or more, 10 μm or more, 15 μm or more, 20 μm or more, or 25 μm or more, from the viewpoint of easily obtaining a resist pattern having a sufficient thickness. From these viewpoints, the thickness of the layer of the photosensitive resin composition or the cured product may be 1 to 100 μm. The thickness of the layer of the photosensitive resin composition or the cured product may be an average thickness of ten places thereof. As for the thickness of the layer of the photosensitive resin composition, although the thickness at the time of measurement of the exposure dose a is 25 μm, any thickness can be adopted in other situations where the photosensitive resin composition is used.

The photosensitive resin composition of the present embodiment contains a binder polymer as the component (A). Examples of the component (A) include an acrylic resin, a styrene-based resin, an epoxy-based resin, an amide-based resin, an amide-epoxy-based resin, an alkyd-based resin, and a phenol-based resin. The acrylic resin is a resin that has a compound having a (meth)acryloyl group ((meth)acrylic acid compound) as a monomer unit, and a styrene-based resin, an epoxy-based resin, an amide-based resin, an amide-epoxy-based resin, an alkyd-based resin, and a phenol-based resin that have this monomer unit attribute to the acrylic resin. The component (A) may not include a binder polymer having a phenolic hydroxyl group.

The component (A) may contain an acrylic resin from the viewpoint of easily obtaining excellent etching solution resistance in the cured product while obtaining excellent sensitivity. The content of the acrylic resin may be 50% by mass or more, more than 50% by mass, 70% by mass or more, 90% by mass or more, 95% by mass or more, 98% by mass or more, 99% by mass or more, or substantially 100% by mass (an embodiment in which the component (A) is substantially composed of the acrylic resin), on the basis of the total amount of the component (A), from the viewpoint of easily obtaining excellent etching solution resistance in the cured product while obtaining excellent sensitivity.

Examples of the compound having a (meth)acryloyl group include a (meth)acrylic acid and a (meth)acrylic acid ester. Examples of the (meth)acrylic acid ester include alkyl(meth)acrylate (alkyl(meth)acrylate ester; excluding a compound corresponding to cycloalkyl(meth)acrylate), cycloalkyl(meth)acrylate (cycloalkyl(meth)acrylate ester), aryl(meth)acrylate (aryl(meth)acrylate ester), a (meth)acrylamide compound (such as diacetone acrylamide), and glycidyl(meth)acrylate ester.

The component (A) may have a (meth)acrylic acid as a monomer unit from the viewpoint of easily obtaining excellent etching solution resistance in the cured product while obtaining excellent sensitivity. In a case where the component (A) has a (meth)acrylic acid as a monomer unit, the content of the monomer unit of the (meth)acrylic acid may be in the following range on the basis of the total amount of monomer units constituting the component (A) from the viewpoint of easily obtaining excellent etching solution resistance in the cured product while obtaining excellent sensitivity. The content of the monomer unit of the (meth)acrylic acid may be 1% by mass or more, 5% by mass or more, 10% by mass or more, 12% by mass or more, 15% by mass or more, 18% by mass or more, 20% by mass or more, 21% by mass or more, 22% by mass or more, 23% by mass or more, 24% by mass or more, 25% by mass or more, 27% by mass or more, or 30% by mass or more. The content of the monomer unit of the (meth)acrylic acid may be 50% by mass or less, less than 50% by mass, 45% by mass or less, 40% by mass or less, 37% by mass or less, 35% by mass or less, 32% by mass or less, 30% by mass or less, 27% by mass or less, 25% by mass or less, 24% by mass or less, 23% by mass or less, or 22% by mass or less. From these viewpoints, the content of the monomer unit of the (meth)acrylic acid may be 1 to 50% by mass.

The component (A) may have alkyl(meth)acrylate as a monomer unit from the viewpoint of easily obtaining excellent etching solution resistance in the cured product while obtaining excellent sensitivity. Examples of the alkyl group of the alkyl(meth)acrylate include a methyl group, an ethyl group, a propyl group, a butyl group, a pentyl group, a hexyl group, a heptyl group, an octyl group, an ethylhexyl group (for example, 2-ethylhexyl group), a nonyl group, a decyl group, an undecyl group, and a dodecyl group, and the alkyl group may be various structural isomers. The component (A) may include alkyl(meth)acrylate in which the number of carbon atoms of the alkyl group is 1 to 10, 1 to 8, 1 to 6, 1 to 4, 1 to 3, 1 to 2, 2 to 8, 3 to 8, 4 to 8, or 6 to 8, from the viewpoint of easily obtaining excellent etching solution resistance in the cured product while obtaining excellent sensitivity.

The alkyl group of the alkyl(meth)acrylate may have a substituent. Examples of the substituent include a hydroxy group, a carboxy group, a carboxylate group, an aldehyde group, an alkoxy group (an unsubstituted alkoxy group (a structure having an unsubstituted alkyl group bonded to an oxygen atom), or substituted alkoxy group (such as a hydroxyalkoxy group)), a carbonyl group, an alkoxycarbonyl group, an alkanoyl group (such as an alkanoyl group having 2 to 12 carbon atoms), an oxycarbonyl group, a carbonyloxy group, an amino group, an epoxy group, a furyl group, a cyano group, a halogeno group (such as a fluoro group, a chloro group, and a bromo group), a nitro group, an acetyl group, a sulfonyl group, and a sulfonamide group. Examples of the alkyl(meth)acrylate include hydroxyalkyl(meth)acrylate, dimethylaminoethyl(meth)acrylate, diethylaminoethyl(meth)acrylate, 2,2,2-trifluoroethyl(meth)acrylate, 2,2,3,3-tetrafluoropropyl(meth)acrylate, α-chloro (meth)acrylic acid, and α-bromo(meth)acrylic acid.

In a case where the component (A) has alkyl(meth)acrylate as a monomer unit, the content of the monomer unit of the alkyl(meth)acrylate may be in the following range on the basis of the total amount of monomer units constituting the component (A) from the viewpoint of easily obtaining excellent etching solution resistance in the cured product while obtaining excellent sensitivity. The content of the monomer unit of the alkyl(meth)acrylate may be 1% by mass or more, 5% by mass or more, 10% by mass or more, 15% by mass or more, 20% by mass or more, 25% by mass or more, 30% by mass or more, 35% by mass or more, 40% by mass or more, 45% by mass or more, 50% by mass or more, 53% by mass or more, 55% by mass or more, 60% by mass or more, 65% by mass or more, 70% by mass or more, 75% by mass or more, or 76% by mass or more. The content of the monomer unit of the alkyl(meth)acrylate may be 99% by mass or less, 95% by mass or less, 90% by mass or less, 85% by mass or less, 80% by mass or less, 76% by mass or less, 75% by mass or less, 70% by mass or less, 65% by mass or less, 60% by mass or less, 55% by mass or less, 53% by mass or less, 50% by mass or less, 45% by mass or less, or 40% by mass or less. From these viewpoints, the content of the monomer unit of the alkyl(meth)acrylate may be 1 to 99% by mass.

The component (A) may have a styrene compound (excluding a compound having a (meth)acryloyl group) as a monomer unit from the viewpoint of easily obtaining excellent etching solution resistance in the cured product while obtaining excellent sensitivity. Examples of the styrene compound include styrene and a styrene derivative. Examples of the styrene derivative include vinyl toluene and α-methylstyrene. From the viewpoint of easily obtaining excellent etching solution resistance in the cured product while obtaining excellent sensitivity, the component (A) may have a (meth)acrylic acid and a styrene compound as monomer units and may have a (meth)acrylic acid, alkyl (meth)acrylate, and a styrene compound as monomer units.

In a case where the component (A) has a styrene compound as a monomer unit, the content of the monomer unit of the styrene compound may be in the following range on the basis of the total amount of monomer units constituting the component (A) from the viewpoint of easily obtaining excellent etching solution resistance in the cured product while obtaining excellent sensitivity. The content of the monomer unit of the styrene compound may be 1% by mass or more, 5% by mass or more, 10% by mass or more, 12% by mass or more, 15% by mass or more, 18% by mass or more, 20% by mass or more, more than 20% by mass, 21% by mass or more, 22% by mass or more, 23% by mass or more, 25% by mass or more, 27% by mass or more, or 30% by mass or more. The content of the monomer unit of the styrene compound may be 50% by mass or less, less than 50% by mass, 45% by mass or less, 40% by mass or less, 37% by mass or less, 35% by mass or less, 32% by mass or less, 30% by mass or less, 27% by mass or less, or 25% by mass or less. From these viewpoints, the content of the monomer unit of the styrene compound may be 1 to 50% by mass or 1 to 30% by mass.

The component (A) may have other monomer as a monomer unit.

Examples of such monomer include ethers of vinyl alcohol (such as vinyl-n-butyl ether), (meth)acrylonitrile, maleic acid, maleic anhydride, maleic acid monoesters (such as monomethyl maleate, monoethyl maleate, and monoisopropyl maleate), fumaric acid, cinnamic acid, α-cyanocinnamic acid, itaconic acid, crotonic acid, and propiolic acid.

In the component (A), the content of the monomer unit of a compound X1 not having an aromatic hydrocarbon group and an alicyclic hydrocarbon group may be in the following range on the basis of the total amount of monomer units constituting the component (A). The content of the monomer unit of the compound X1 may be 80% by mass or less, less than 80% by mass, 70% by mass or less, 60% by mass or less, 50% by mass or less, 40% by mass or less, 35% by mass or less, 30% by mass or less, or 25% by mass or less. The content of the monomer unit of the compound X1 may be 0% by mass or more, more than 0% by mass, 1% by mass or more, 5% by mass or more, 10% by mass or more, 15% by mass or more, 20% by mass or more, or 25% by mass or more. From these viewpoints, the content of the monomer unit of the compound X1 may be 0 to 80% by mass, more than 0% by mass and 80% by mass or less, 5 to 60% by mass, or 10 to 40% by mass.

The weight average molecular weight (Mw) of the component (A) may be in the following range from the viewpoint of easily obtaining excellent etching solution resistance in the cured product while obtaining excellent sensitivity. The weight average molecular weight of the component (A) may be 1.0×10⁴ or more, 2.0×10⁴ or more, 2.5×10⁴ or more, 3.0×10⁴ or more, more than 3.0×10⁴, 3.1×10⁴ or more, 3.3×10⁴ or more, 3.5×10⁴ or more, 4.0×10⁴ or more, 4.5×10⁴ or more, 4.7×10⁴ or more, or 5.0×10⁴ or more. The weight average molecular weight of the component (A) may be 10×10⁴ or less, 8.0×10⁴ or less, 7.0×10⁴ or less, less than 7.0×10⁴, 6.5×10⁴ or less, 6.0×10⁴ or less, 5.5×10⁴ or less, 5.0×10⁴ or less, 4.7×10⁴ or less, 4.5×10⁴ or less, 4.0×10⁴ or less, 3.5×10⁴ or less, or 3.0×10⁴ or less. From these viewpoints, the weight average molecular weight of the component (A) may be 1.0×10⁴ to 10×10⁴, 2.0×10⁴ to 6.0×10⁴, or 3.0×10⁴ to 5.0×10⁴.

The weight average molecular weight can be measured, for example, by gel permeation chromatography (GPC) using a calibration curve of standard polystyrene. More specifically, it is possible to measure under conditions described in Examples. As for a compound having a low molecular weight, in a case where measurement of the weight average molecular weight is difficult using the above-described method of measuring a weight average molecular weight, it is also possible to measure the molecular weights using other methods and to calculate an average value thereof.

The content of the component (A) may be in the following range on the basis of the total amount (the total amount of solid contents) of the photosensitive resin composition from the viewpoint of easily obtaining excellent etching solution resistance in the cured product while obtaining excellent sensitivity. The content of the component (A) may be 10% by mass or more, 20% by mass or more, 30% by mass or more, 35% by mass or more, 40% by mass or more, 45% by mass or more, or 50% by mass or more. The content of the component (A) may be 90% by mass or less, 85% by mass or less, 80% by mass or less, 75% by mass or less, 70% by mass or less, 65% by mass or less, 60% by mass or less, or 55% by mass or less. From these viewpoints, the content of the component (A) may be 10 to 90% by mass, 30 to 80% by mass, or 40 to 70% by mass.

The content of the component (A) may be in the following range with respect to a total of 100 parts by mass of the component (A) and the component (B) from the viewpoint of easily obtaining excellent etching solution resistance in the cured product while obtaining excellent sensitivity. The content of the component (A) may be 10 parts by mass or more, 20 parts by mass or more, 30 parts by mass or more, 35 parts by mass or more, 40 parts by mass or more, 45 parts by mass or more, 50 parts by mass or more, 54 parts by mass or more, 55 parts by mass or more, or 56 parts by mass or more. The content of the component (A) may be 90 parts by mass or less, 80 parts by mass or less, 75 parts by mass or less, 70 parts by mass or less, 65 parts by mass or less, 60 parts by mass or less, 56 parts by mass or less, 55 parts by mass or less, or 54 parts by mass or less. From these viewpoints, the content of the component (A) may be 10 to 90 parts by mass, 30 to 80 parts by mass, or 40 to 70 parts by mass.

In the photosensitive resin composition of the present embodiment, the content of a resin having a phenolic hydroxyl group may be 30% by mass or less, less than 30% by mass, 20% by mass or less, 10% by mass or less, 5% by mass or less, 1% by mass or less, or 0.1% by mass or less, on the basis of the total amount (the total amount of solid contents) of the photosensitive resin composition. The photosensitive resin composition of the present embodiment may not contain a resin having a phenolic hydroxyl group (the above-described content may be substantially 0% by mass).

The photosensitive resin composition of the present embodiment contains a photopolymerizable compound as the component (B). The photopolymerizable compound is a compound that is polymerized by light, and may be a compound having an ethylenically unsaturated bond.

The component (B) includes, as a component (b1), a polyfunctional compound having three or more ethylenically unsaturated bonds. From the viewpoint of easily obtaining excellent etching solution resistance in the cured product while obtaining excellent sensitivity, the component (B) may include, as the component (b1), a (meth)acrylic acid compound having three or more (meth)acryloyl groups (tri- or higher functional (meth)acrylic acid compound: a compound in which the sum of the acryloyl group and the methacryloyl group is 3 or more).

The component (B) may include, as the component (b1), a polyfunctional compound in which the number of ethylenically unsaturated bonds is in the following range. The number of ethylenically unsaturated bonds in the component (b1) is 3 or more, and may be 4 or more, 5 or more, or 6 or more from the viewpoint of easily obtaining excellent etching solution resistance in the cured product while obtaining excellent sensitivity. The number of ethylenically unsaturated bonds in the component (b1) may be 10 or less, 8 or less, 6 or less, 5 or less, or 4 or less. From these viewpoints, the number of ethylenically unsaturated bonds in the component (b1) may be 3 to 10.

From the viewpoint of easily obtaining excellent etching solution resistance in the cured product while obtaining excellent sensitivity, the component (B) may include, as the component (b1), a polyfunctional compound having three ethylenically unsaturated bonds, and may include a polyfunctional compound having six ethylenically unsaturated bonds. The component (B) may include two or more kinds of the component (b1), and may include a polyfunctional compound having three ethylenically unsaturated bonds and a polyfunctional compound having six ethylenically unsaturated bonds from the viewpoint of easily obtaining excellent etching solution resistance in the cured product while obtaining excellent sensitivity.

The number of (meth)acryloyl groups (the sum of the acryloyl group and the methacryloyl group) in the component (b1) may be 3 or more, 4 or more, 5 or more, or 6 or more from the viewpoint of easily obtaining excellent etching solution resistance in the cured product while obtaining excellent sensitivity. The number of (meth)acryloyl groups in the component (b1) may be 10 or less, 8 or less, 6 or less, 5 or less, or 4 or less. From these viewpoints, the number of (meth)acryloyl groups in the component (b1) may be 3 to 10.

Examples of the component (b1) include trimethylolpropane tri(meth)acrylate; alkylene oxide-modified trimethylolpropane tri(meth)acrylates such as EO-modified trimethylolpropane tri(meth)acrylate, PO-modified trimethylolpropane tri(meth)acrylate, and

EO/PO-modified trimethylolpropane tri(meth)acrylate; tetramethylolmethane tri(meth)acrylate; tetramethylolmethane tetra(meth)acrylate; pentaerythritol tetra(meth)acrylate; alkylene oxide-modified pentaerythritol tetra(meth)acrylates such as EO-modified pentaerythritol tetra(meth)acrylate, PO-modified pentaerythritol tetra(meth)acrylate, and EO/PO-modified pentaerythritol tetra(meth)acrylate; dipentaerythritol hexa(meth)acrylate; and alkylene oxide-modified dipentaerythritol hexa(meth)acrylates such as EO-modified dipentaerythritol hexa(meth)acrylate, PO-modified dipentaerythritol hexa(meth)acrylate, and EO/PO-modified dipentaerythritol hexa(meth)acrylate. In the photosensitive resin composition of the first embodiment, from the viewpoint of easily obtaining excellent etching solution resistance in the cured product while obtaining excellent sensitivity, the component (B) may include, as the component (b1), at least one selected from the group consisting of trimethylolpropane tri(meth)acrylate, alkylene oxide-modified trimethylolpropane tri(meth)acrylate, dipentaerythritol hexa(meth)acrylate, and alkylene oxide-modified dipentaerythritol hexa(meth)acrylate, and may include alkylene oxide-modified trimethylolpropane tri(meth)acrylate. In the photosensitive resin composition of the second embodiment, the component (B) includes at least one selected from the group consisting of trimethylolpropane tri(meth)acrylate, alkylene oxide-modified trimethylolpropane tri(meth)acrylate, dipentaerythritol hexa(meth)acrylate, and alkylene oxide-modified dipentaerythritol hexa(meth)acrylate, and may include alkylene oxide-modified trimethylolpropane tri(meth)acrylate.

From the viewpoint of easily obtaining excellent etching solution resistance in the cured product while obtaining excellent sensitivity, as the component (b1), the component (B) may include a (meth)acrylic acid compound having a polyoxyalkylene group, may include at least one selected from the group consisting of alkylene oxide-modified trimethylolpropane tri(meth)acrylate and alkylene oxide-modified dipentaerythritol hexa(meth)acrylate, and may include at least one selected from the group consisting of EO-modified trimethylolpropane tri(meth)acrylate, PO-modified trimethylolpropane tri(meth)acrylate, EO/PO-modified trimethylolpropane tri(meth)acrylate, EO-modified dipentaerythritol hexa(meth)acrylate, PO-modified dipentaerythritol hexa(meth)acrylate, and EO/PO-modified dipentaerythritol hexa(meth)acrylate.

The molecular weight of the component (b1) may be in the following range from the viewpoint of easily obtaining excellent etching solution resistance in the cured product while obtaining excellent sensitivity. The molecular weight may be 100 or more, 200 or more, 300 or more, 400 or more, 500 or more, 600 or more, 700 or more, 750 or more, 800 or more, 900 or more, 1000 or more, 1100 or more, or 1200 or more. The molecular weight may be 10000 or less, less than 10000, 8000 or less, 6000 or less, 5000 or less, 3000 or less, 2000 or less, 1500 or less, 1300 or less, 1200 or less, 1100 or less, 1000 or less, 900 or less, 800 or less, 750 or less, 700 or less, 600 or less, or 500 or less. From these viewpoints, the molecular weight may be 100 to 10000.

The (meth)acryloyl group concentration (the total number of (meth)acryloyl groups in one molecule/molecular weight; the same applies hereinafter) of the component (b1) may be in the following range from the viewpoint of easily obtaining excellent etching solution resistance in the cured product while obtaining excellent sensitivity. The (meth)acryloyl group concentration may be 1×10⁻³ or more, 2×10⁻³ or more, 3×10⁻³ or more, 4×10⁻³ or more, 5×10⁻³ or more, 6×10⁻³ or more, or 7×10⁻³ or more. The (meth)acryloyl group concentration may be 1×10⁻² or less, 9×10⁻³ or less, 8×10⁻³ or less, 7×10⁻³ or less, 6×10⁻³ or less, 5×10⁻³ or less, 4×10⁻³ or less, or 3×10⁻³ or less. From these viewpoints, the (meth)acryloyl group concentration may be 1×10⁻³ to 1×10⁻².

The content of the component (b1) is more than 0% by mass on the basis of the total amount of the component (B), and may be in the following range from the viewpoint of easily obtaining excellent etching solution resistance in the cured product while obtaining excellent sensitivity. The content of the component (b1) may be 1% by mass or more, 2% by mass or more, 3% by mass or more, 4% by mass or more, 5% by mass or more, 8% by mass or more, 10% by mass or more, 15% by mass or more, 18% by mass or more, 20% by mass or more, 25% by mass or more, or 30% by mass or more. The content of the component (b1) may be 50% by mass or less, less than 50% by mass, 40% by mass or less, 30% by mass or less, 25% by mass or less, 20% by mass or less, 18% by mass or less, 15% by mass or less, 10% by mass or less, 8% by mass or less, or 5% by mass or less. From these viewpoints, the content of the component (b1) may be more than 0% by mass and 50% by mass or less, 1 to 40% by mass, or 3 to 30% by mass.

The content of the component (b1) is more than 0% by mass on the basis of the total amount (the total amount of solid contents) of the photosensitive resin composition, and may be in the following range from the viewpoint of easily obtaining excellent etching solution resistance in the cured product while obtaining excellent sensitivity. The content of the component (b1) may be 0.1% by mass or more, 0.5% by mass or more, 1% by mass or more, 2% by mass or more, 3% by mass or more, 5% by mass or more, 7% by mass or more, 8% by mass or more, 9% by mass or more, 10% by mass or more, 12% by mass or more, or 13% by mass or more. The content of the component (b1) may be 30% by mass or less, 25% by mass or less, 20% by mass or less, 15% by mass or less, 13% by mass or less, 12% by mass or less, 10% by mass or less, 9% by mass or less, 8% by mass or less, 7% by mass or less, 5% by mass or less, 3% by mass or less, or 2% by mass or less. From these viewpoints, the content of the component (b1) may be more than 0% by mass and 30% by mass or less, 0.1 to 20% by mass, or 1 to 10% by mass.

The content of the component (b1) is more than 0 parts by mass with respect to a total of 100 parts by mass of the component (A) and the component (B), and may be in the following range from the viewpoint of easily obtaining excellent etching solution resistance in the cured product while obtaining excellent sensitivity. The content of the component (b1) may be 1 part by mass or more, 2 parts by mass or more, 3 parts by mass or more, 4 parts by mass or more, 5 parts by mass or more, 6 parts by mass or more, 7 parts by mass or more, 8 parts by mass or more, 9 parts by mass or more, 10 parts by mass or more, 12 parts by mass or more, or 14 parts by mass or more. The content of the component (b1) may be 30 parts by mass or less, 25 parts by mass or less, 20 parts by mass or less, 15 parts by mass or less, 14 parts by mass or less, 12 parts by mass or less, 10 parts by mass or less, 9 parts by mass or less, 8 parts by mass or less, 7 parts by mass or less, 6 parts by mass or less, 5 parts by mass or less, 4 parts by mass or less, 3 parts by mass or less, or 2 parts by mass or less. From these viewpoints, the content of the component (b1) may be more than 0 parts by mass and 30 parts by mass or less, 0.1 to 20 parts by mass, or 1 to 10 parts by mass.

In the photosensitive resin composition of the first embodiment, the component (B) may include, as a component (b2), a photopolymerizable compound not corresponding to the component (b1). In the photosensitive resin composition of the second embodiment, as the component (b2), the component (B) includes 2,2-bis(4-((meth)acryloxypentaethoxy)phenyl)propane described below, and may further include a photopolymerizable compound not corresponding to the component (b1) and 2,2-bis(4-((meth)acryloxypentaethoxy)phenyl)propane.

The component (b2) may be a compound having an ethylenically unsaturated bond (a monofunctional compound having one ethylenically unsaturated bond or a compound having two ethylenically unsaturated bonds), and may be a compound having a (meth)acryloyl group ((meth)acrylic acid compound). Examples of the component (b2) include a bisphenol A-type (meth)acrylic acid compound, EO-modified di(meth)acrylate, PO-modified di(meth)acrylate, EO/PO-modified di(meth)acrylate, polyalkylene glycol di(meth)acrylate (such as polyethylene glycol di(meth)acrylate and polypropylene glycol di(meth)acrylate), EO-modified polyalkylene glycol di(meth)acrylate, PO-modified polyalkylene glycol di(meth)acrylate, EO/PO-modified polyalkylene glycol di(meth)acrylate, trimethylolpropane di(meth)acrylate, nonylphenol alkylene oxide-modified (meth)acrylate (for example, nonylphenol EO-modified (meth)acrylate (also known as: nonylphenoxypolyethyleneoxy (meth)acrylate)), a phthalic acid-based compound (γ-chloro-β-hydroxypropyl-β′-(meth)acryloyloxyethyl-o-phthalate (also known as: 1-(3-chloro-2-hydroxypropyl) 2-[2-((meth)acryloyloxy)ethyl]) phthalate), alkyl(meth)acrylate, and a photopolymerizable compound having at least one cationic polymerizable cyclic ether group in the molecule (such as an oxetane compound). From the viewpoint of easily obtaining excellent etching solution resistance in the cured product while obtaining excellent sensitivity, the component (B) may include, as the component (b2), a bisphenol A-type (meth)acrylic acid compound.

From the viewpoint of easily obtaining excellent etching solution resistance in the cured product while obtaining excellent sensitivity, the component (B) may include, as the component (b2), a (meth)acrylic acid compound having a polyoxyalkylene group, and may include a bisphenol A-type (meth)acrylic acid compound having a polyoxyalkylene group. Examples of the bisphenol A-type (meth)acrylic acid compound having a polyoxyalkylene group include 2,2-bis(4-((meth)acryloxypolyethoxy)phenyl)propane, 2,2-bis(4-((meth)acryloxypolypropoxy)phenyl)propane, 2,2-bis(4-((meth)acryloxypolybutoxy)phenyl)propane, and 2,2-bis(4-((meth)acryloxypolyethoxypolypropoxy)phenyl)propane.

The component (B) may include 2,2-bis(4-((meth)acryloxypolyethoxy)phenyl)propane in which the number of ethylene oxides added is in the following range, from the viewpoint of easily obtaining excellent etching solution resistance in the cured product while obtaining excellent sensitivity. The number of ethylene oxides added may be 2 mol or more, 4 mol or more, 6 mol or more, 8 mol or more, or 10 mol or more. The number of ethylene oxides added may be 20 mol or less, 16 mol or less, 12 mol or less, 10 mol or less, 8 mol or less, 6 mol or less, or 4 mol or less. From these viewpoints, the number of ethylene oxides added may be 2 to 20 mol, 2 to 12 mol, 2 to 10 mol, 2 to 8 mol, 6 to 20 mol, 6 to 12 mol, or 6 to 10 mol.

In the photosensitive resin composition of the first embodiment, from the viewpoint of easily obtaining excellent etching solution resistance in the cured product while obtaining excellent sensitivity, the component (B) may include 2,2-bis(4-((meth)acryloxypolyethoxy)phenyl)propane, may include at least one selected from the group consisting of 2,2-bis(4-((meth)acryloxypentaethoxy)phenyl)propane and 2,2-bis(4-((meth)acryloxydiethoxy)phenyl)propane, and may include 2,2-bis(4-((meth)acryloxypentaethoxy)phenyl)propane. In the photosensitive resin composition of the second embodiment, the component (B) includes 2,2-bis(4-((meth)acryloxypentaethoxy)phenyl)propane, and may include 2,2-bis(4-((meth)acryloxypentaethoxy)phenyl)propane and 2,2-bis(4-((meth)acryloxydiethoxy)phenyl)propane from the viewpoint of easily obtaining excellent etching solution resistance in the cured product while obtaining excellent sensitivity.

The molecular weight of the component (b2) (for example, bisphenol A-type (meth)acrylic acid compound) may be in the following range from the viewpoint of easily obtaining excellent etching solution resistance in the cured product while obtaining excellent sensitivity. The molecular weight may be 100 or more, 200 or more, 300 or more, 400 or more, 450 or more, 500 or more, 550 or more, 600 or more, 650 or more, 700 or more, 750 or more, or 800 or more. The molecular weight may be 10000 or less, less than 10000, 8000 or less, 6000 or less, 5000 or less, 3000 or less, 2000 or less, 1500 or less, 1000 or less, or 900 or less. From these viewpoints, the molecular weight may be 100 to 10000.

The (meth)acryloyl group concentration of the component (b2) (for example, bisphenol A-type (meth)acrylic acid compound) may be in the following range from the viewpoint of easily obtaining excellent etching solution resistance in the cured product while obtaining excellent sensitivity. The (meth)acryloyl group concentration may be 1×10⁴ or more, 5×10⁻⁴ or more, 1×10⁻³ or more, 1.5×10⁻³ or more, 2×10⁻³ or more, or 2.4×10⁻³ or more. The (meth)acryloyl group concentration may be 1×10⁻² or less, 9×10⁻³ or less, 8×10⁻³ or less, 7×10⁻³ or less, 6×10⁻³ or less, 5×10⁻³ or less, 4×10⁻³ or less, or 3×10⁻³ or less. From these viewpoints, the (meth)acryloyl group concentration may be 1×10⁴ to 1×10⁻².

The content of the bisphenol A-type (meth)acrylic acid compound is less than 100% by mass on the basis of the total amount of the component (B), and may be in the following range from the viewpoint of easily obtaining excellent etching solution resistance in the cured product while obtaining excellent sensitivity. The content of the bisphenol A-type (meth)acrylic acid compound may be 50% by mass or more, more than 50% by mass, 60% by mass or more, 70% by mass or more, 75% by mass or more, 80% by mass or more, 82% by mass or more, 85% by mass or more, 90% by mass or more, 92% by mass or more, or 95% by mass or more. The content of the bisphenol A-type (meth)acrylic acid compound may be 99% by mass or less, 98% by mass or less, 97% by mass or less, 96% by mass or less, 95% by mass or less, 92% by mass or less, 90% by mass or less, 85% by mass or less, 82% by mass or less, 80% by mass or less, 75% by mass or less, or 70% by mass or less. From these viewpoints, the content of the bisphenol A-type (meth)acrylic acid compound may be 50% by mass or more and less than 100% by mass, 60 to 99% by mass, or 70 to 97% by mass.

The content of the bisphenol A-type (meth)acrylic acid compound is less than 100% by mass on the basis of the total amount (the total amount of solid contents) of the photosensitive resin composition, and may be in the following range from the viewpoint of easily obtaining excellent etching solution resistance in the cured product while obtaining excellent sensitivity. The content of the bisphenol A-type (meth)acrylic acid compound may be 1% by mass or more, 5% by mass or more, 10% by mass or more, 15% by mass or more, 20% by mass or more, 25% by mass or more, 30% by mass or more, 32% by mass or more, 35% by mass or more, 36% by mass or more, 37% by mass or more, 38% by mass or more, or 40% by mass or more. The content of the bisphenol A-type (meth)acrylic acid compound may be 80% by mass or less, 70% by mass or less, 65% by mass or less, 60% by mass or less, 55% by mass or less, 50% by mass or less, 45% by mass or less, 40% by mass or less, 38% by mass or less, 37% by mass or less, 36% by mass or less, 35% by mass or less, or 32% by mass or less. From these viewpoints, the content of the bisphenol A-type (meth)acrylic acid compound may be 1% by mass or more and less than 100% by mass, 1 to 80% by mass, 10 to 70% by mass, or 30 to 50% by mass.

The content of the bisphenol A-type (meth)acrylic acid compound may be in the following range with respect to a total of 100 parts by mass of the component (A) and the component (B) from the viewpoint of easily obtaining excellent etching solution resistance in the cured product while obtaining excellent sensitivity. The content of the bisphenol A-type (meth)acrylic acid compound may be 1 part by mass or more, 5 parts by mass or more, 10 parts by mass or more, 15 parts by mass or more, 20 parts by mass or more, 25 parts by mass or more, 30 parts by mass or more, 32 parts by mass or more, 35 parts by mass or more, 36 parts by mass or more, 37 parts by mass or more, 38 parts by mass or more, 39 parts by mass or more, 40 parts by mass or more, 41 parts by mass or more, 42 parts by mass or more, or 44 parts by mass or more. The content of the bisphenol A-type (meth)acrylic acid compound may be 80 parts by mass or less, 70 parts by mass or less, 60 parts by mass or less, 50 parts by mass or less, 45 parts by mass or less, 44 parts by mass or less, 42 parts by mass or less, 41 parts by mass or less, 40 parts by mass or less, 39 parts by mass or less, 38 parts by mass or less, 37 parts by mass or less, 36 parts by mass or less, 35 parts by mass or less, or 32 parts by mass or less. From these viewpoints, the content of the bisphenol A-type (meth)acrylic acid compound may be 1 to 80 parts by mass, 10 to 70 parts by mass, or 30 to 50 parts by mass.

The content of the monofunctional compound having one ethylenically unsaturated bond may be in the following range on the basis of the total amount of the component (B). The content of the monofunctional compound may be 20% by mass or less, 15% by mass or less, 12% by mass or less, 10% by mass or less, 5% by mass or less, 3% by mass or less, 2% by mass or less, 1% by mass or less, 0.1% by mass or less, or 0.01% by mass or less, from the viewpoint of easily obtaining excellent etching solution resistance in the cured product while obtaining excellent sensitivity. The content of the monofunctional compound may be 0% by mass or more, more than 0% by mass, 0.01% by mass or more, 0.1% by mass or more, 1% by mass or more, 2% by mass or more, 3% by mass or more, 5% by mass or more, or 10% by mass or more.

From these viewpoints, the content of the monofunctional compound may be 0 to 20% by mass, 0 to 10% by mass, or 5 to 20% by mass.

The content of the monofunctional compound having one ethylenically unsaturated bond may be in the following range on the basis of the total amount (the total amount of solid contents) of the photosensitive resin composition. The content of the monofunctional compound may be 10% by mass or less, 8% by mass or less, 5% by mass or less, 4% by mass or less, 3% by mass or less, 1% by mass or less, less than 1% by mass, 0.1% by mass or less, or 0.01% by mass or less, from the viewpoint of easily obtaining excellent etching solution resistance in the cured product while obtaining excellent sensitivity. The content of the monofunctional compound may be 0% by mass or more, more than 0% by mass, 0.01% by mass or more, 0.1% by mass or more, 1% by mass or more, 3% by mass or more, or 4% by mass or more. From these viewpoints, the content of the monofunctional compound may be 0 to 10% by mass, 0 to 4% by mass, or 0% by mass or more and less than 1% by mass.

The content of the monofunctional compound having one ethylenically unsaturated bond may be in the following range with respect to a total of 100 parts by mass of the component (A) and the component (B). The content of the monofunctional compound may be 10 parts by mass or less, 8 parts by mass or less, 5 parts by mass or less, 4 parts by mass or less, 3 parts by mass or less, 1 part by mass or less, less than 1 part by mass, 0.1 parts by mass or less, or 0.01 parts by mass or less, from the viewpoint of easily obtaining excellent etching solution resistance in the cured product while obtaining excellent sensitivity. The content of the monofunctional compound may be 0 parts by mass or more, more than 0 parts by mass, 0.01 parts by mass or more, 0.1 parts by mass or more, 1 part by mass or more, 3 parts by mass or more, 4 parts by mass or more, or 5 parts by mass or more. From these viewpoints, the content of the monofunctional compound may be 0 to 10 parts by mass, 0 to 4 parts by mass, or 0 parts by mass or more and less than 1 part by mass.

The content of the component (B) may be in the following range on the basis of the total amount (the total amount of solid contents) of the photosensitive resin composition from the viewpoint of easily obtaining excellent etching solution resistance in the cured product while obtaining excellent sensitivity. The content of the component (B) may be 10% by mass or more, 15% by mass or more, 20% by mass or more, 25% by mass or more, 30% by mass or more, 35% by mass or more, 40% by mass or more, or 43% by mass or more. The content of the component (B) may be 90% by mass or less, 80% by mass or less, 70% by mass or less, 65% by mass or less, 60% by mass or less, 55% by mass or less, 50% by mass or less, or 45% by mass or less. From these viewpoints, the content of the component (B) may be 10 to 90% by mass, 20 to 70% by mass, or 30 to 60% by mass.

The content of the component (B) may be in the following range with respect to a total of 100 parts by mass of the component (A) and the component (B) from the viewpoint of easily obtaining excellent etching solution resistance in the cured product while obtaining excellent sensitivity. The content of the component (B) may be 10 parts by mass or more, 20 parts by mass or more, 25 parts by mass or more, 30 parts by mass or more, 35 parts by mass or more, 40 parts by mass or more, 44 parts by mass or more, 45 parts by mass or more, or 46 parts by mass or more. The content of the component (B) may be 90 parts by mass or less, 80 parts by mass or less, 70 parts by mass or less, 65 parts by mass or less, 60 parts by mass or less, 55 parts by mass or less, 50 parts by mass or less, 46 parts by mass or less, 45 parts by mass or less, or 44 parts by mass or less. From these viewpoints, the content of the component (B) may be 10 to 90 parts by mass, 20 to 70 parts by mass, or 30 to 60 parts by mass.

In the photosensitive resin composition of the present embodiment, the content of a (meth)acrylic acid compound having an isocyanuric ring structure or the content of a photopolymerizable compound having an ethylenically unsaturated group and an isocyanuric ring structure may be 1 part by mass or less, less than 1 part by mass, 0.1 parts by mass or less, 0.01 parts by mass or less, or 0.001 parts by mass or less with respect to a total of 100 parts by mass of the component (A) and the component (B). The photosensitive resin composition of the present embodiment may not contain a (meth)acrylic acid compound having an isocyanuric ring structure (the above-described content may be substantially 0 parts by mass), and may not contain a photopolymerizable compound having an ethylenically unsaturated group and an isocyanuric ring structure (the above-described content may be substantially 0 parts by mass).

In the photosensitive resin composition of the present embodiment, the content of at least one selected from the group consisting of a photopolymerizable compound having a skeleton derived from pentaerythritol and a photopolymerizable compound having a skeleton derived from dipentaerythritol may be 3 parts by mass or less, less than 3 parts by mass, 1 part by mass or less, 0.1 parts by mass or less, or 0.01 parts by mass or less, with respect to a total of 100 parts by mass of the component (A) and the component (B). The photosensitive resin composition of the present embodiment may not contain at least one selected from the group consisting of a photopolymerizable compound having a skeleton derived from pentaerythritol and a photopolymerizable compound having a skeleton derived from dipentaerythritol (the content thereof may be substantially 0 parts by mass with respect to a total of 100 parts by mass of the component (A) and the component (B)). In the photosensitive resin composition of the present embodiment, the content of at least one selected from the group consisting of a (meth)acrylic acid compound having a skeleton derived from pentaerythritol and a (meth)acrylic acid compound having a skeleton derived from dipentaerythritol may be 3 parts by mass or less, less than 3 parts by mass, 1 part by mass or less, 0.1 parts by mass or less, or 0.01 parts by mass or less, with respect to a total of 100 parts by mass of the component (A) and the component (B). The photosensitive resin composition of the present embodiment may not contain at least one selected from the group consisting of a (meth)acrylic acid compound having a skeleton derived from pentaerythritol and a (meth)acrylic acid compound having a skeleton derived from dipentaerythritol (the content thereof may be substantially 0 parts by mass with respect to a total of 100 parts by mass of the component (A) and the component (B)).

In the photosensitive resin composition of the present embodiment, the content of a bisphenol F-type (meth)acrylic acid compound may be 5% by mass or less, less than 5% by mass, 1% by mass or less, less than 1% by mass, 0.1% by mass or less, or substantially 0% by mass, on the basis of the total amount of the component (B). In the photosensitive resin composition of the present embodiment, the content of a bisphenol F-type (meth)acrylic acid compound may be 0.2% by mass or less, 0.15% by mass or less, less than 0.15% by mass, 0.1% by mass or less, or 0.01% by mass or less, on the basis of the total amount (the total amount of solid contents) of the photosensitive resin composition. The photosensitive resin composition of the present embodiment may not contain a bisphenol F-type (meth)acrylic acid compound (the above-described content may be substantially 0% by mass).

In the photosensitive resin composition of the present embodiment, the content of an epoxy compound having two or more oxirane rings may be 20 parts by mass or less, less than 20 parts by mass, 10 parts by mass or less, less than 10 parts by mass, 1 part by mass or less, or substantially 0 parts by mass, with respect to 100 parts by mass of the component (A). The photosensitive resin composition of the present embodiment may not contain an epoxy compound having two or more oxirane rings (the content of the epoxy compound having two or more oxirane rings may be substantially 0% by mass on the basis of the total amount (the total amount of solid contents) of the photosensitive resin composition).

The photosensitive resin composition of the present embodiment contains a photopolymerization initiator as the component (C).

Examples of the component (C) include acridine compounds such as 9-phenylacridine and 1,7-bis(9,9′-acridinyl) heptane; N-phenylglycine compounds such as N-phenylglycine and a N-phenylglycine derivative; a hexaarylbiimidazole compound; aromatic ketones such as benzophenone, 2-benzyl-2-dimethylamino-1-(4-morpholinophenyl)-1-butanone, 2-(dimethylamino)-2-[(4-methylphenyl)methyl]-1-[4-(4-morpholinyl)phenyl]-1-butanone, 4-(2-hydroxyethoxy)phenyl-2-(hydroxy-2-propyl) ketone, and 2-methyl-1-[4-(methylthio)phenyl]-2-morpholino-propanone-1; quinone compounds such as alkylanthraquinone; benzoinether compounds such as benzoinalkyl ethers; benzoin compounds such as benzoin and alkylbenzoin; benzyl derivatives such as benzyldimethylketal; bis(2,4,6-trimethylbenzoyl)-phenylphosphine oxide; bis(2,6-dimethylbenzoyl)-2,4,4-trimethyl-pentylphosphine oxide; and (2,4,6-trimethylbenzoyl)ethoxyphenylphosphine oxide.

The hexaarylbiimidazole compound may be a 2,4,5-triarylimidazole dimer. Examples of the 2,4,5-triarylimidazole dimer include a 2-(o-chlorophenyl)-4,5-diphenylimidazole dimer, a 2-(o-chlorophenyl)-4,5-bis-(m-methoxyphenyl) imidazole dimer, and a 2-(p-methoxyphenyl)-4,5-diphenylimidazole dimer. From the viewpoint of easily obtaining excellent etching solution resistance in the cured product while obtaining excellent sensitivity, the hexaarylbiimidazole compound may include a 2-(o-chlorophenyl)-4,5-diphenylimidazole dimer, and may include 2,2′-bis(o-chlorophenyl)-4,4′,5,5′-tetraphenyl-1,2′-biimidazole.

In the photosensitive resin composition of the first embodiment, the component (C) may include an acridine compound, may include a N-phenylglycine compound, and may include a hexaarylbiimidazole compound. From the viewpoint of easily obtaining excellent etching solution resistance in the cured product while obtaining excellent sensitivity, the component (C) may include at least one selected from the group consisting of an acridine compound, a N-phenylglycine compound, and a hexaarylbiimidazole compound, may include at least one selected from the group consisting of an acridine compound and a N-phenylglycine compound, and may include an acridine compound and a N-phenylglycine compound. The exposure dose a is easily reduced by using at least one selected from the group consisting of an acridine compound and a N-phenylglycine compound.

In the photosensitive resin composition of the second embodiment, the component (C) includes an acridine compound, and may further include a photopolymerization initiator other than the acridine compound. From the viewpoint of easily obtaining excellent etching solution resistance in the cured product while obtaining excellent sensitivity, the component (C) may include an acridine compound and a N-phenylglycine compound.

In the photosensitive resin composition of the present embodiment, the total amount of the acridine compound and the N-phenylglycine compound may be 50% by mass or more, more than 50% by mass, 70% by mass or more, 90% by mass or more, 95% by mass or more, 98% by mass or more, 99% by mass or more, or substantially 100% by mass (an embodiment in which the component (C) is substantially composed of the acridine compound and the N-phenylglycine compound), on the basis of the total amount of the component (C), from the viewpoint of easily obtaining excellent etching solution resistance in the cured product while obtaining excellent sensitivity.

The content of the acridine compound may be in the following range on the basis of the total amount of the component (C) from the viewpoint of easily obtaining excellent etching solution resistance in the cured product while obtaining excellent sensitivity. The content of the acridine compound may be 50% by mass or more, more than 50% by mass, 70% by mass or more, 80% by mass or more, 90% by mass or more, 95% by mass or more, 96% by mass or more, 97% by mass or more, 98% by mass or more, 98.5% by mass or more, or 99% by mass or more. The content of the acridine compound may be 100% by mass or less, less than 100% by mass, 99% by mass or less, 98% by mass or less, 97% by mass or less, 96% by mass or less, or 95% by mass or less. From these viewpoints, the content of the acridine compound may be 50 to 100% by mass.

The content of the N-phenylglycine compound may be in the following range on the basis of the total amount of the component (C) from the viewpoint of easily obtaining excellent etching solution resistance in the cured product while obtaining excellent sensitivity. The content of the N-phenylglycine compound may be more than 0% by mass, 1% by mass or more, 2% by mass or more, 3% by mass or more, 4% by mass or more, or 5% by mass or more. The content of the N-phenylglycine compound may be 50% by mass or less, less than 50% by mass, 30% by mass or less, 20% by mass or less, 10% by mass or less, 5% by mass or less, 4% by mass or less, 3% by mass or less, 2% by mass or less, or 1.5% by mass or less. From these viewpoints, the content of the N-phenylglycine compound may be more than 0% by mass and 50% by mass or less.

The content of the component (C) may be in the following range on the basis of the total amount (the total amount of solid contents) of the photosensitive resin composition from the viewpoint of easily obtaining excellent etching solution resistance in the cured product while obtaining excellent sensitivity. The content of the component (C) may be 0.1% by mass or more, 0.3% by mass or more, 0.5% by mass or more, 0.8% by mass or more, 0.9% by mass or more, 1% by mass or more, 1.1% by mass or more, 1.2% by mass or more, 1.5% by mass or more, 2% by mass or more, 2.5% by mass or more, 3% by mass or more, or 3.5% by mass or more. The content of the component (C) may be 10% by mass or less, 5% by mass or less, 3.5% by mass or less, 3% by mass or less, 2.5% by mass or less, 2% by mass or less, 1.5% by mass or less, 1.2% by mass or less, 1.1% by mass or less, 1% by mass or less, 0.9% by mass or less, 0.8% by mass or less, or 0.5% by mass or less. From these viewpoints, the content of the component (C) may be 0.1 to 10% by mass.

The content of the component (C) may be in the following range with respect to a total of 100 parts by mass of the component (A) and the component (B) from the viewpoint of easily obtaining excellent etching solution resistance in the cured product while obtaining excellent sensitivity. The content of the component (C) may be 0.1 parts by mass or more, 0.3 parts by mass or more, 0.5 parts by mass or more, 0.8 parts by mass or more, 0.9 parts by mass or more, 1 part by mass or more, 1.1 parts by mass or more, 1.2 parts by mass or more, 1.3 parts by mass or more, 1.5 parts by mass or more, 2 parts by mass or more, 2.5 parts by mass or more, 3 parts by mass or more, 3.5 parts by mass or more, or 4 parts by mass or more. The content of the component (C) may be 10 parts by mass or less, 5 parts by mass or less, 4 parts by mass or less, 3.5 parts by mass or less, 3 parts by mass or less, 2.5 parts by mass or less, 2 parts by mass or less, 1.5 parts by mass or less, 1.3 parts by mass or less, 1.2 parts by mass or less, 1.1 parts by mass or less, 1 part by mass or less, 0.9 parts by mass or less, 0.8 parts by mass or less, or 0.5 parts by mass or less. From these viewpoints, the content of the component (C) may be 0.1 to 10 parts by mass.

The photosensitive resin composition of the present embodiment may contain a polymerization inhibitor (excluding a compound corresponding to any one of the components (A) to (C)), and may not contain a polymerization inhibitor. Examples of the polymerization inhibitor include a catechol compound (for example, tert-butylcatechol such as 4-tert-butylcatechol), hindered amine (for example, 2,2,6,6-tetramethyl-4-hydroxypiperidine-1-oxyl), and 4-hydroxy-2,2,6,6-tetramethylpiperidine-N-oxyl.

The photosensitive resin composition of the present embodiment may contain an organic solvent (excluding a compound corresponding to any one of the components (A) to (C)). Examples of the organic solvent include methanol, ethanol, acetone, methyl ethyl ketone, methyl cellosolve, ethyl cellosolve, toluene, N,N-dimethylformamide, and propylene glycol monomethyl ether.

The photosensitive resin composition of the present embodiment may contain other component (excluding a compound corresponding to any one of the components (A) to (C)). Examples of other component include hydrogen donors (such as bis[4-(dimethylamino)phenyl]methane, bis[4-(diethylamino)phenyl]methane, and leuco crystal violet, N-phenylglycine), dyes (such as malachite green), tribromophenylsulfone, tribromomethyl phenyl sulfone, a vinyl polymer, an oxetane compound, an anthracene compound (such as 9,10-dibutoxyanthracene), a distyrylbenzene compound, a naphthalene compound, a nitroxyl compound, a mercapto compound (a compound having a mercapto group; such as 2-mercaptobenzimidazole), sensitizers, photochromic agents, thermochromic inhibitors, plasticizers (such as p-toluenesulfonamide), pigments, fillers, antifoaming agents, flame retardants, stabilizers, tackifiers, leveling agents, release promoters, antioxidants, aromatics, imaging agents, thermal crosslinking agents, and thermal radical polymerization initiators. From the viewpoint of easily obtaining excellent etching solution resistance in the cured product while obtaining excellent sensitivity, the photosensitive resin composition of the present embodiment may contain tribromomethyl phenyl sulfone.

In the photosensitive resin composition of the present embodiment, the content of the thermal radical polymerization initiator may be 0.5% by mass or less, less than 0.5% by mass, 0.1% by mass or less, 0.01% by mass or less, or 0.001% by mass or less, on the basis of the total amount (the total amount of solid contents) of the photosensitive resin composition. The photosensitive resin composition of the present embodiment may not contain a thermal radical polymerization initiator (the above-described content may be substantially 0% by mass).

In the photosensitive resin composition of the present embodiment, the content of at least one selected from the group consisting of a vinyl polymer (for example, a vinyl polymer having a side chain having an epoxy group) and an oxetane compound (for example, an oxetane compound having two or more oxetane rings which may have a substituent) may be 20% by mass or less, less than 20% by mass, 10% by mass or less, 1% by mass or less, 0.1% by mass or less, 0.01% by mass or less, or 0.001% by mass or less, on the basis of the total amount (the total amount of solid contents) of the photosensitive resin composition. The photosensitive resin composition of the present embodiment may not contain at least one selected from the group consisting of a vinyl polymer (for example, a vinyl polymer having a side chain having an epoxy group) and an oxetane compound (for example, an oxetane compound having two or more oxetane rings which may have a substituent) (the above-described content may be substantially 0% by mass).

In the photosensitive resin composition of the present embodiment, the content of at least one selected from the group consisting of an anthracene compound, a distyrylbenzene compound, and a naphthalene compound may be 0.01% by mass or less, less than 0.01% by mass, 0.001% by mass or less, or 0.0001% by mass or less, on the basis of the total amount (the total amount of solid contents) of the photosensitive resin composition. The photosensitive resin composition of the present embodiment may not contain at least one selected from the group consisting of an anthracene compound, a distyrylbenzene compound, and a naphthalene compound (the above-described content may be substantially 0% by mass).

In the photosensitive resin composition of the present embodiment, the content of the nitroxyl compound may be 0.005 parts by mass or less, less than 0.005 parts by mass, 0.001 parts by mass or less, or 0.0001 parts by mass or less with respect to 100 parts by mass of the component (A) or a total of 100 parts by mass of the component (A) and the component (B). The photosensitive resin composition of the present embodiment may not contain a nitroxyl compound (the above-described content may be substantially 0 parts by mass).

In the photosensitive resin composition of the present embodiment, the content of the mercapto compound may be 0.1 parts by mass or less, less than 0.1 parts by mass, 0.001 parts by mass or less, less than 0.001 parts by mass, or 0.0001 parts by mass or less with respect to a total of 100 parts by mass of the component (A) and the component (B). The photosensitive resin composition of the present embodiment may not contain a mercapto compound (the above-described content may be substantially 0 parts by mass).

In the photosensitive resin composition of the present embodiment, the content of a compound X2 with a weight average molecular weight of less than 20000 having one ethylenically unsaturated bond and at least one selected from the group consisting of an aromatic hydrocarbon group and an alicyclic hydrocarbon group may be 1 part by mass or less, less than 1 part by mass, 0.1 parts by mass or less, or 0.01 parts by mass or less with respect to a total of 100 parts by mass of the component (A) and the component (B). The photosensitive resin composition of the present embodiment may not contain the compound X2 (the above-described content may be substantially 0 parts by mass). The number of the ethylenically unsaturated bond in the compound X2 is 1. The weight average molecular weight of the compound X2 can be measured by the same procedure as in the weight average molecular weight of the component (A).

In the photosensitive resin composition of the present embodiment, the content of an acid-modified vinyl group-containing epoxy resin may be 20% by mass or less, less than 20% by mass, 10% by mass or less, 1% by mass or less, 0.1% by mass or less, or 0.01% by mass or less, on the basis of the total amount (the total amount of solid contents) of the photosensitive resin composition. The photosensitive resin composition of the present embodiment may not contain an acid-modified vinyl group-containing epoxy resin (the above-described content may be substantially 0% by mass). The acid-modified vinyl group-containing epoxy resin can be obtained by modifying the epoxy resin with an acid having a vinyl group.

In the photosensitive resin composition of the present embodiment, the content of an acyl phosphine oxide-based photopolymerization initiator may be 0.2% by mass or less, less than 0.2% by mass, 0.1% by mass or less, 0.01% by mass or less, or 0.001% by mass or less, on the basis of the total amount (the total amount of solid contents) of the photosensitive resin composition. The photosensitive resin composition of the present embodiment may not contain an acyl phosphine oxide-based photopolymerization initiator (the above-described content may be substantially 0% by mass).

### <Photosensitive Element>

A photosensitive element of the present embodiment includes a support and a photosensitive resin layer disposed on the support, and the photosensitive resin layer is a layer of the photosensitive resin composition of the present embodiment. The photosensitive element of the present embodiment may include a protective layer disposed on the photosensitive resin layer. The photosensitive element of the present embodiment may include a cushion layer, an adhesive layer, a light-absorbing layer, a gas barrier layer, or the like. The photosensitive element may be in a sheet form, or may be in the form of a photosensitive element roll being wound around a core into a roll.

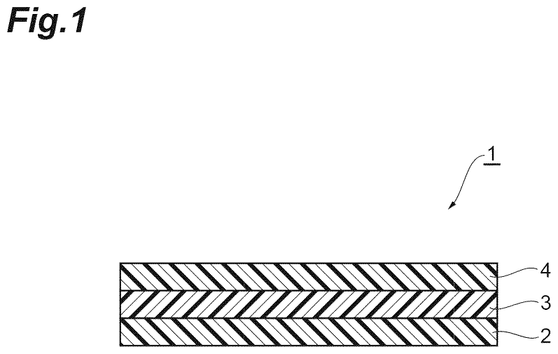

FIG. 1 is a schematic cross-sectional view illustrating an example of a photosensitive element. As illustrated in FIG. 1, a photosensitive element 1 includes a support (support film) 2, a photosensitive resin layer 3 disposed on the support 2, and a protective layer (protective film) 4 disposed on the photosensitive resin layer 3. The photosensitive resin layer 3 is composed of the photosensitive resin composition of the present embodiment.

The photosensitive element 1 can be obtained, for example, by the following procedure. First, the photosensitive resin layer 3 is formed on the support 2. The photosensitive resin layer 3 can be formed, for example, by drying a coating layer formed by applying a photosensitive resin composition containing an organic solvent. Next, the protective layer 4 is disposed on the photosensitive resin layer 3.

Each of the support and the protective layer may be a polymer film having heat resistance and solvent resistance, and may be a polyester film (such as a polyethylene terephthalate film), a polyolefin film (such as a polyethylene film or a polypropylene film), a hydrocarbon-based polymer (excluding a polyolefin film), or the like. The type of the film constituting the protective layer and the type of the film constituting the support may be the same as or different from each other.

The thickness of the support may be 1 μm or more, 5 μm or more, 10 μm or more, or 15 μm or more, from the viewpoint of easily suppressing the damage of the support when the support is peeled off from the photosensitive resin layer. The thickness of the support may be 100 μm or less, 50 μm or less, 30 μm or less, or 20 μm or less, from the viewpoint of suitably performing exposure in the case of exposure through the support.

The thickness of the protective layer may be 1 μm or more, 5 μm or more, 10 μm or more, or 15 μm or more, from the viewpoint of easily suppressing the damage of the protective layer when the photosensitive resin layer and the support are laminated on the base material while the protective layer is peeled off. The thickness of the protective layer may be 100 μm or less, 50 μm or less, or 30 μm or less, from the viewpoint of easily improving productivity.

### <Method for Producing Laminate>

A method for producing a laminate of the present embodiment includes a disposing step (photosensitive resin layer disposing step) of disposing a photosensitive resin layer (a layer of the photosensitive resin composition) on a base material by using the photosensitive resin composition of the present embodiment or the photosensitive element of the present embodiment, an exposure step of photo-curing (exposing) a part of the photosensitive resin layer, and a development step of removing at least a part of an uncured area (unexposed area) of the photosensitive resin layer to form a cured product pattern. The photosensitive resin composition in the disposing step may be a photosensitive resin composition of the photosensitive element of the present embodiment. A laminate of the present embodiment is obtained by the method for producing a laminate of the present embodiment, and may be a wiring board (for example, a printed circuit board). The laminate of the present embodiment may be an embodiment having a base material and a cured product pattern (the cured product of the present embodiment) disposed on the base material.

In the disposing step, a photosensitive resin layer composed of the photosensitive resin composition of the present embodiment is disposed on a base material. For example, the photosensitive resin layer may be formed by removing the protective layer from the photosensitive element and then pressure-bonding the photosensitive resin layer of the photosensitive element to the base material while heating the photosensitive resin layer, and may be formed by applying the photosensitive resin composition onto the base material and drying the photosensitive resin composition.

In the exposure step, a region other than a region of the photosensitive resin layer in which a mask is disposed may be exposed and photo-cured by irradiation with an active light ray in a state where the mask is disposed on the photosensitive resin layer, and a part of the photosensitive resin layer may be exposed and photo-cured by irradiation with an active light ray at a desired pattern by a direct writing exposure method such as an LDI exposure method or a DLP exposure method without using a mask. As the light source for the active light ray, an ultraviolet source or a visible light source may be used and examples thereof include a carbon arc lamp, a mercury vapor arc lamp, a high-pressure mercury lamp, a xenon lamp, a gas laser (such as an argon laser), a solid-state laser (such as a YAG laser), and a semiconductor laser.

The development method in the development step may be, for example, wet development or dry development. The wet development can be performed using a developing solution suitable for the photosensitive resin composition, for example, by methods such as a dip method, a paddle method, a spray method, brushing, slapping, scrubbing, and dipping while shaking. The developing solution is appropriately selected in accordance with the configuration of the photosensitive resin composition, and may be an alkaline developing solution or an organic solvent developing solution.

The alkaline developing solution may be aqueous solutions containing bases such as alkali hydroxides such as hydroxides of lithium, sodium, or potassium; alkali carbonates such as carbonates or bicarbonates of lithium, sodium, potassium, or ammonium; alkali metal phosphates such as potassium phosphate and sodium phosphate; alkali metal pyrophosphate such as sodium pyrophosphate and potassium pyrophosphate; borax; sodium metasilicate; tetramethylammonium hydroxide; ethanolamine; ethylenediamine; diethylene triamine; 2-amino-2-hydroxymethyl-1,3-propanediol; 1,3-diamino-2-propanol; and morpholine.

The organic solvent developing solution may contain an organic solvent such as 1,1,1-trichloroethane, N-methylpyrrolidone, N,N-dimethylformamide, cyclohexanone, methyl isobutyl ketone, and γ-butyrolactone.

The base material may have a metal layer, and the photosensitive resin layer may be in contact with the metal layer. In this case, the method for producing a laminate of the present embodiment may include an etching step of etching the metal layer by using the cured product pattern as a mask to remove a part of the metal layer after the development step. In the etching step, a portion where a cured product pattern is not formed in the metal layer (a portion which was covered with the uncured area in the metal layer) can be removed. The metal layer may contain, for example, copper. An etching solution may contain hydrochloric acid, and may contain hydrochloric acid and cupric chloride.

The method for producing a laminate of the present embodiment may include a step of further curing a resist pattern by heating at 60 to 250° C. or exposure at 0.2 to 10 J/cm² after the development step.

The method for producing a laminate of the present embodiment may include a step of removing the cured product pattern after the etching step. The cured product pattern can be removed, for example, by performing development with a dipping method, a spraying method, or the like using a strong alkaline aqueous solution.

### Examples

Hereinafter, the present disclosure will be further specifically described by means of Examples; however, the present disclosure is not limited to these Examples. Various operations such as exposure and development described below were performed at room temperature (25° C.) under atmospheric pressure as long as conditions were not particularly stated.

### <Synthesis of Binder Polymer>

### (Binder Polymer A1)

A solution (a) was prepared by mixing 22.0 parts by mass of methacrylic acid, 50.0 parts by mass of methyl methacrylate, 3.0 parts by mass of 2-ethylhexyl acrylate, 25.0 parts by mass of styrene, and 0.9 parts by mass of azobisisobutyronitrile. A solution (b) was prepared by dissolving 0.5 parts by mass of azobisisobutyronitrile in 100 parts by mass of acetone. After charging acetone in a flask equipped with a stirrer, a reflux condenser, a thermometer, a dropping funnel, and a nitrogen gas inlet tube, stirring was performed while blowing nitrogen gas into the flask, and the temperature was raised to 80° C. The solution (a) was added dropwise to the above-described flask over 4 hours at a constant dropwise addition rate, and then the solution in the flask was stirred at 80° C. for 2 hours. Next, the solution (b) was added dropwise to the above-described flask over 10 minutes at a constant dropwise addition rate, and then the solution in the flask was stirred at 80° C. for 3 hours. Further, the solution in the flask was heated to 95° C. over 1 hour and kept at 90° C. for 2 hours, stirring was then stopped, and the solution was cooled to room temperature (25° C.), thereby obtaining a solution of a binder polymer A1. The non-volatile content (solid content) of the solution of the binder polymer A1 was 49% by mass.

### (Binder Polymer A2)

A solution of a binder polymer A2 was obtained by performing the operation in the same manner as in the binder polymer A1, except that a solution (a) was prepared by mixing 24.0 parts by mass of methacrylic acid, 43.5 parts by mass of methyl methacrylate, 15.2 parts by mass of butyl acrylate, 17.3 parts by mass of butyl methacrylate, and 0.9 parts by mass of azobisisobutyronitrile. The non-volatile content (solid content) of the solution of the binder polymer A2 was 49% by mass.

### (Binder Polymer A3)

A solution of a binder polymer A3 was obtained by performing the operation in the same manner as in the binder polymer A1, except that a solution (a) was prepared by mixing 30.0 parts by mass of methacrylic acid, 22.0 parts by mass of methyl methacrylate, 10.0 parts by mass of ethyl acrylate, 8.0 parts by mass of butyl methacrylate, 30.0 parts by mass of styrene, and 0.9 parts by mass of azobisisobutyronitrile. The non-volatile content (solid content) of the solution of the binder polymer A3 was 49% by mass.

### (Binder Polymer A4)

A solution (a) was prepared by mixing 29.0 parts by mass of methacrylic acid, 26.0 parts by mass of methyl methacrylate, 45.0 parts by mass of styrene, and 0.9 parts by mass of azobisisobutyronitrile. A solution (b) was prepared by dissolving 0.5 parts by mass of azobisisobutyronitrile in 100 parts by mass of toluene. After charging toluene in a flask equipped with a stirrer, a reflux condenser, a thermometer, a dropping funnel, and a nitrogen gas inlet tube, stirring was performed while blowing nitrogen gas into the flask, and the temperature was raised to 80° C. The solution (a) was added dropwise to the above-described flask over 4 hours at a constant dropwise addition rate, and then the solution in the flask was stirred at 80° C. for 2 hours. Next, the solution (b) was added dropwise to the above-described flask over 10 minutes at a constant dropwise addition rate, and then the solution in the flask was stirred at 80° C. for 3 hours. Further, the solution in the flask was heated to 95° C. over 1 hour and kept at 90° C. for 2 hours, stirring was then stopped, and the solution was cooled to room temperature (25° C.), thereby obtaining a solution of a binder polymer A4. The non-volatile content (solid content) of the solution of the binder polymer A4 was 49% by mass.

### (Binder Polymer A5)

A solution of a binder polymer A5 was obtained by performing the operation in the same manner as in the binder polymer A4, except that a solution (a) was prepared by mixing 27.0 parts by mass of methacrylic acid, 50.0 parts by mass of styrene, 3.0 parts by mass of 2-hydroxyethyl methacrylate, 20 parts by mass of benzyl methacrylate, and 0.9 parts by mass of azobisisobutyronitrile. The non-volatile content (solid content) of the solution of the binder polymer A5 was 49% by mass.

### <Weight Average Molecular Weight (Mw) of Binder Polymer>

The weight average molecular weight of the binder polymer A1 was 4.7×10⁴, the weight average molecular weight of the binder polymer A2 was 3.0×10⁴, the weight average molecular weight of the binder polymer A3 was 5.0×10⁴, the weight average molecular weight of the binder polymer A4 was 3.0×10⁴, and the weight average molecular weight of the binder polymer A5 was 3.5×10⁴. The weight average molecular weight was obtained by measuring with gel permeation chromatography (GPC) under the following conditions and converting using a calibration curve of standard polystyrene. The measurement was performed using a sample obtained by dissolving 120 mg of the solution of the binder polymer in 5 mL of tetrahydrofuran.

### (Gpc Conditions)

Pump: Hitachi L-6000 type (manufactured by Hitachi, Ltd., trade name)
Column: Three columns below in total (manufactured by Showa Denko Materials Techno Service Co., Ltd., trade name, column specification: 10.7 mmϕ×300 mm)
   Gelpack GL-R440
   Gelpack GL-R450
   Gelpack GL-R400M
Eluent: Tetrahydrofuran
Measurement temperature: 40° C.
Injection amount: 200 μL
Pressure: 49 kgf/cm² (4.8 MPa)
Flow rate: 2.05 mL/min
Detector: Hitachi L-2490 type RI (manufactured by Hitachi, Ltd., trade name)

### <Preparation of Photosensitive Resin Composition>

A photosensitive resin composition was prepared by mixing each component shown in Table 1 or Table 2, 16 parts by mass of toluene, 6 parts by mass of methanol, and 10 parts by mass of acetone. Table 1 and Table 2 show the blending amount (parts by mass) of each component, and the blending amount of the binder polymer is the mass (solid content amount) of the non-volatile content. The details of respective components shown in Table 1 and Table 2 are as follows.

### (Photopolymerizable Compound)

### [Tri- or Higher Functional Photopolymerizable Compound]

FA-137M: EO-modified trimethylolpropane trimethacrylate (manufactured by Showa Denko Materials Co., Ltd., functionality number: 3, molecular weight: 1263, (meth)acryloyl group concentration: 2.38×10⁻³)
M3130: EO-modified trimethylolpropane triacrylate (manufactured by TOYO CHEMICALS CO., LTD., functionality number: 3, molecular weight: 428, (meth)acryloyl group concentration: 7.01×10⁻³)
DPEA-12: EO-modified dipentaerythritol hexaacrylate (manufactured by Nippon Kayaku Co., Ltd., functionality number: 6, molecular weight: 1105, (meth)acryloyl group concentration: 5.43×10⁻³)

### [Bifunctional Photopolymerizable Compound]

FA-321M (70): 2,2-Bis(4-(methacryloxypentaethoxy)phenyl)propane (an adduct of an average of 10 mol of ethylene oxide, EO-modified bisphenol A dimethacrylate, manufactured by Showa Denko Materials Co., Ltd., functionality number: 2, molecular weight: 804, (meth)acryloyl group concentration: 2.49×10⁻³)
BP-2EM: 2,2-Bis(4-(methacryloxydiethoxy)phenyl)propane (EO-modified bisphenol A dimethacrylate, Kyoeisha Chemical Co., Ltd.)
BPE-200: Ethoxylated bisphenol A dimethacrylate (an adduct of an average of 4 mol of ethylene oxide, manufactured by SHIN-NAKAMURA CHEMICAL Co., Ltd.)
M2200: Ethoxylated bisphenol A dimethacrylate (an adduct of an average of 20 mol of ethylene oxide, manufactured by Miwon)
FA-024M: EO/PO-modified dimethacrylate (manufactured by Showa Denko Materials Co., Ltd., functionality number: 2, molecular weight: 1115, (meth)acryloyl group concentration: 1.79)

### [Monofunctional Photopolymerizable Compound]

FA-MECH: γ-Chloro-β-hydroxypropyl-β′-methacryloyloxyethyl-o-phthalate (manufactured by Showa Denko Materials Co., Ltd.)

### (Photopolymerization Initiator)

9-PA: 9-Phenylacridine (manufactured by Changzhou Tronly New Electronic Materials Co., Ltd.)
N-PG: N-Phenylglycine (manufactured by Changzhou Tronly New Electronic Materials Co., Ltd.)
BCIM: 2,2′-Bis(o-chlorophenyl)-4,4′,5,5′-tetraphenyl-1,2′-biimidazole (manufactured by Hampford Research Inc.)

### (Other Components)

LCV: Leuco crystal violet (manufactured by Yamada Chemical Co., Ltd.)
TPS: Tribromomethyl phenyl sulfone (manufactured by Changzhou Tronly New Electronic Materials Co., Ltd.)
MKG: Malachite green (manufactured by OSAKA ORGANIC CHEMICAL INDUSTRY LTD.)
LA-7RD: 4-Hydroxy-2,2,6,6-tetramethylpiperidine-N-oxyl (manufactured by Asahi Denka Co., Ltd.)
SF-808H: Mixture of carboxybenzotriazole, 5-amino-1H-tetrazole, and methoxypropanol (manufactured by SANWA KASEI CORP.)
PTSA: p-Toluenesulfonamide (manufactured by JMC)
DBA: 9,10-Dibutoxyanthracene (manufactured by Kawasaki Kasei Chemicals Ltd.)
TBC: 4-tert-Butylcatechol (manufactured by DIC Corporation, trade name “DIC-TBC-5P”)
MBI: 2-Mercaptobenzimidazole (manufactured by Sigma-Aldrich Corporation)
T. A. GREEN 2580: Mixture of Solvent Blue 70 derivative and amine salt of Solvent Yellow 21 (manufactured by Tokyo Aniline Dye Mfg. Co., Ltd.)
FA-711 MM: Pentamethylpiperidinyl methacrylate (manufactured by Showa Denko Materials Co., Ltd.)

### <Production of Photosensitive Element>

As a support, a polyethylene terephthalate film (manufactured by Teijin Film Solutions Limited, trade name “G2J”, thickness: 16 μm) was prepared. The above-described photosensitive resin composition was applied onto the support to have an uniform thickness and then sequentially dried with a hot air convection drier set at 70° C. and 110° C. to form a photosensitive resin layer (photosensitive film; average thickness of ten places after drying: 25 μm). A polyethylene film (manufactured by TAMAPOLY CO., LTD., trade name “NF-13”, thickness: 17 μm) as the protective layer was attached onto this photosensitive resin layer, thereby obtaining a photosensitive element having the support, the photosensitive resin layer, and the protective layer in this order.

### <Production of Laminate>

A copper-clad laminate plate (substrate, manufactured by Showa Denko Materials Co., Ltd., trade name: MCL-E-67) having copper foils (thickness: 18 μm) disposed on both surfaces of a glass epoxy material was pickled, rinsed, and then dried with an air stream to obtain a base material. Next, this base material was heated to 80° C., and then the above-described photosensitive element was laminated so that the photosensitive resin layer was in contact with the copper surface while the protective layer was peeled off, thereby obtaining a laminate having the base material (copper-clad laminate plate), the photosensitive resin layer, and the support in this order. The lamination was performed using a heat roll set at 110° C. at a pressure-bonding pressure of 0.4 MPa and at a roll speed of 1.0 m/min.

### <Sensitivity>

After a 41-step tablet (manufactured by Showa Denko Materials Co., Ltd., concentration region 0.00 to 2.00, concentration step 0.05, tablet size 20 mm×187 mm, each step size 3 mm×12 mm) was placed on the support of the above-described laminate, the photosensitive resin layer was exposed through the support at an exposure dose (irradiation energy dose) for 15 steps remaining on the 41-step tablet after the development by a direct writing exposure machine (manufactured by Orbotech, Nuvogo Fine 8, light source: 375 nm (0%)+405 nm (100%)). The sensitivity (photosensitivity) was evaluated using the exposure dose (unit: mJ/cm²) at this time. The development was performed by peeling off the support and then subjecting an unexposed photosensitive resin layer to spray development (nozzle: full-cone type nozzle, distance between an object to be treated and a nozzle tip: 6 cm) at a pressure of 0.15 MPa using a 1% by mass sodium carbonate aqueous solution set at 30° C. Results are shown in Table 1 and Table 2.

### <Minimum Developing Time>

The above-described laminate was cut into a square shape (5 cm×5 cm) and then the support was peeled off, thereby obtaining a test specimen. Then, an unexposed photosensitive resin layer in the test specimen was subjected to spray development (nozzle: full-cone type nozzle, distance between an object to be treated and a nozzle tip: 6 cm) at a pressure of 0.15 MPa using a 1% by mass sodium carbonate aqueous solution set at 30° C., and the shortest time that allowed the removal of the unexposed photosensitive resin layer to be visually confirmed was obtained as a minimum developing time (MD).

### <Etching Solution Resistance>

After a 41-step tablet (the same tablet as in the above-described sensitivity evaluation) was placed on the support of the above-described laminate, a 3 cm×4 cm pattern was exposed for the photosensitive resin layer of the above-described laminate through the support at an exposure dose obtained in the above-described sensitivity evaluation by a direct writing exposure machine (manufactured by Orbotech, Nuvogo Fine 8, light source: 375 nm (0%)+405 nm (100%)). Next, after the photosensitive resin layer was exposed by peeling off the support, an unexposed photosensitive resin layer was subjected to spray development (nozzle: full-cone type nozzle, distance between an object to be treated and a nozzle tip: 6 cm) at a pressure of 0.15 MPa for twice the minimum developing time using a 1% by mass sodium carbonate aqueous solution set at 30° C., thereby obtaining a test specimen having a pattern (cured product of the photosensitive resin layer).

Next, a 300 mL etching solution (aqueous solution) containing 5.5 mol/L of hydrochloric acid and 2.1 mol/L of cupric chloride was accommodated in a beaker having a volume of 300 mL, and then the temperature of the etching solution was adjusted to 70° C. Subsequently, while the etching solution was stirred (stirring condition: 425 to 475 rpm), the test specimen was placed perpendicular to the beaker bottom in a state where the pattern surface of the test specimen faced the center of the beaker, and the test specimen was immersed in the etching solution for 10 minutes.

After the test specimen was taken out from the etching solution, the test specimen was washed with running water, and whether or not peeling or floating occurs in the pattern during washing was visually checked. After washing, the test specimen was dried with air by an air duster gun, and whether or not peeling or floating occurs in the pattern during drying was visually checked. The “floating” is a phenomenon that at least a part of the outer periphery of the pattern is peeled off from the base material, and the “peeling” is a phenomenon that the center of the pattern is peeled off from the base material. A case where peeling and floating are not confirmed during washing and drying was evaluated as “A”, a case where peeling and floating are not confirmed during washing but floating is confirmed during drying was evaluated as “B”, a case where peeling is not confirmed during washing but floating is confirmed during washing was evaluated as “C”, and a case where peeling is confirmed during washing was evaluated as “D”. The case of “A” or “B” was determined to be favorable. Results are shown in Table 1 and Table 2.

TABLE 1

| | | Example | | | | | | | | | |
|---|---|---|---|---|---|---|---|---|---|---|---|
| | | 1 | 2 | 3 | 4 | 5 | 6 | 7 | 8 | 9 | 10 |
| Binder polymer | A1 | 54.0 | 54.0 | 54.0 | 54.0 | 54.0 | 54.0 | 54.0 | 54.0 | 51.0 | |
| | A2 | | | | | | | | | 5.0 | |
| | A3 | | | | | | | | | | 56.0 |
| Photopolymerizable | FA-137M | 2.0 | | | 4.0 | 4.0 | 4.0 | 4.0 | 2.0 | 3.0 | 5.0 |
| compound | M3130 | | 2.0 | | 5.0 | | | | 3.5 | | |
| | DPEA-12 | | | 10.0 | | 5.0 | 5.0 | 10.0 | 2.0 | | |
| | FA-321M(70) | 44.0 | 44.0 | 36.0 | 37.0 | 37.0 | 32.0 | 32.0 | 38.5 | 41.0 | 39.0 |
| | FA-MECH | | | | | | 5.0 | | | | |
| Photopolymerization | 9-PA | 1.00 | 1.20 | 1.20 | 1.20 | 1.20 | 1.20 | 0.50 | 0.90 | | 0.50 |
| initiator | N-PG | 0.02 | 0.04 | 0.03 | 0.03 | 0.03 | 0.03 | | 0.01 | | 0.03 |
| | BCIM | | | | | | | | | 4.0 | |
| Other components | LCV | 1.0 | 1.0 | 1.0 | 1.0 | 1.0 | 1.0 | 0.9 | 1.0 | 0.6 | 1.0 |
| | TPS | 0.8 | 0.8 | 0.8 | 0.8 | 0.8 | 0.8 | 0.7 | 0.8 | | 1.1 |
| | MKG | 0.03 | 0.03 | 0.03 | 0.03 | 0.03 | 0.03 | 0.03 | 0.03 | 0.03 | 0.03 |
| | LA-7RD | 0.02 | 0.02 | 0.02 | 0.02 | 0.02 | 0.02 | 0.005 | 0.02 | 0.01 | 0.01 |
| | SF-808H | 0.5 | 0.5 | 0.5 | 0.5 | 0.5 | 0.5 | 0.5 | 0.5 | 1.0 | 1.0 |
| | PTSA | 2.0 | 2.0 | 2.0 | 2.0 | 2.0 | 2.0 | 2.0 | 2.0 | 2.0 | |
| | DBA | | | | | | | | | 0.45 | |
| | TBC | | | | | | | | | 0.003 | |
| | MBI | | | | | | | | | 0.06 | |

| | | | | | | | | | | |
|---|---|---|---|---|---|---|---|---|---|---|
| Sensitivity [mJ/cm²] | 15 | 14 | 15 | 20 | 20 | 23 | 22 | 18 | 28 | 25 |
| Etching solution resistance | B | B | A | B | A | B | A | A | B | B |

TABLE 2

| | | | | | | | | Reference |
|---|---|---|---|---|---|---|---|---|
| | | Comparative Example | | | | | | Example |
| | | 1 | 2 | 3 | 4 | 5 | 6 | 1 |
| Binder polymer | A1 | 54.0 | 56.0 | 56.0 | 56.0 | 51.0 | | |
| | A2 | | | | | 5.0 | | |
| | A4 | | | | | | 53.0 | |
| | A5 | | | | | | | 56.0 |
| Photopolymerizable | FA-137M | | 5.0 | 5.0 | 5.0 | 5.0 | | |
| compound | M3130 | 5.0 | | | | | | |
| | FA-321M(70) | 38.0 | 39.0 | 39.0 | 39.0 | 39.0 | 36.8 | 35.0 |
| | BP-2EM | 3.0 | | | | | | 5.0 |
| | BPE-200 | | | | | | 2.4 | |
| | FA-MECH | | | | | | 6.5 | |
| | M2200 | | | | | | 1.3 | |
| | FA-024M | | | | | | | 4.0 |
| Photopolymerization | 9-PA | 0.65 | | | | | 0.50 | |
| initiator | N-PG | 0.03 | | | | | 0.03 | |
| | BCIM | | 4.0 | 4.0 | 4.0 | 4.0 | | 6.0 |
| Other components | LCV | 0.9 | 0.6 | 0.6 | 0.6 | 0.6 | 1.5 | 0.5 |
| | TPS | 0.7 | | | | | 1.1 | |
| | MKG | 0.03 | 0.03 | 0.03 | 0.03 | 0.03 | 0.02 | 0.02 |
| | LA-7RD | 0.09 | 0.01 | 0.01 | 0.01 | 0.01 | 0.01 | 0.01 |
| | SF-808H | 0.3 | 1.0 | 1.0 | 1.0 | 1.0 | 1.5 | 0.5 |
| | PTSA | 1.0 | 2.0 | 2.0 | 2.0 | 2.0 | | |
| | DBA | | 0.45 | 0.45 | 0.45 | 0.45 | | 0.65 |
| | TBC | | 0.005 | | 0.003 | 0.003 | | 0.015 |
| | MBI | | | | 0.02 | 0.02 | | |
| | T.A. GREEN 2580 | | | | | | 0.02 | |
| | FA-711MM | | | | | | | 1.0 |

| | | | | | | | |
|---|---|---|---|---|---|---|---|
| Sensitivity [mJ/cm²] | 74 | 60 | 49 | 37 | 33 | 16 | 53 |
| Etching solution resistance | C | C | C | C | C | D | A |

### REFERENCE SIGNS LIST

1: photosensitive element, 2: support, 3: photosensitive resin layer, 4: protective layer.

1. A photosensitive resin composition comprising: (A) a binder polymer; (B) a photopolymerizable compound; and (C) a photopolymerization initiator, wherein
the component (B) includes a polyfunctional compound having three or more ethylenically unsaturated bonds, and
in a case where development is performed after exposing a layer (thickness 25 μm) of the photosensitive resin composition at a wavelength of 405 nm using a 41-step tablet (concentration region 0.00 to 2.00, concentration step 0.05, tablet size 20 mm×187 mm, each step size 3 mm×12 mm), an exposure dose providing 15 steps as the number of remaining steps is 30 mJ/cm² or less.

2. The photosensitive resin composition according to claim 1, wherein the component (B) includes a polyfunctional compound having three ethylenically unsaturated bonds.

3. The photosensitive resin composition according to claim 1, wherein the component (B) includes a polyfunctional compound having six ethylenically unsaturated bonds.

4. The photosensitive resin composition according to claim 1, wherein the component (B) includes a polyfunctional compound having three ethylenically unsaturated bonds and a polyfunctional compound having six ethylenically unsaturated bonds.

5. The photosensitive resin composition according to claim 1, wherein the component (C) includes an acridine compound.

6. The photosensitive resin composition according to claim 1, wherein the component (C) includes an acridine compound and a N-phenylglycine compound.

7. The photosensitive resin composition according to claim 1, wherein a content of the polyfunctional compound is 1 to 10% by mass on the basis of the total amount of the photosensitive resin composition.

8. The photosensitive resin composition according to claim 1, wherein a content of the polyfunctional compound is 3 to 30% by mass on the basis of the total amount of the component (B).

9. The photosensitive resin composition according to claim 1, wherein the component (B) further includes a bisphenol A-type (meth)acrylic acid compound.

10. The photosensitive resin composition according to claim 1, wherein a content of the component (B) is 30 to 60 parts by mass with respect to a total of 100 parts by mass of the component (A) and the component (B).

11. The photosensitive resin composition according to claim 1, wherein the component (A) has a (meth)acrylic acid and a styrene compound as monomer units.

12. The photosensitive resin composition according to claim 1, wherein the component (A) has a styrene compound as a monomer unit, and
a content of the monomer unit of the styrene compound is 1 to 30% by mass on the basis of the total amount of monomer units constituting the component (A).

13. The photosensitive resin composition according to claim 1, wherein a weight average molecular weight of the component (A) is 3.0×10⁴ to 5.0×10⁴.

14. A photosensitive resin composition comprising: (A) a binder polymer; (B) a photopolymerizable compound; and (C) a photopolymerization initiator, wherein
the component (B) includes at least one selected from the group consisting of trimethylolpropane tri(meth)acrylate, alkylene oxide-modified trimethylolpropane tri(meth)acrylate, dipentaerythritol hexa(meth)acrylate, and alkylene oxide-modified dipentaerythritol hexa(meth)acrylate, and 2,2-bis(4-((meth)acryloxypentaethoxy)phenyl)propane, and
the component (C) includes an acridine compound.

15. The photosensitive resin composition according to claim 14, wherein the component (B) includes alkylene oxide-modified trimethylolpropane tri(meth)acrylate.

16. The photosensitive resin composition according to claim 14, further comprising tribromomethyl phenyl sulfone.

17. The photosensitive resin composition according to claim 1, which is in a film form.

18. A photosensitive element comprising: a support; and a photosensitive resin layer disposed on the support, wherein
the photosensitive resin layer is a layer of the photosensitive resin composition according to claim 1.

19. A method for producing a laminate, the method comprising:
a step of disposing a layer of the photosensitive resin composition on a base material by using the photosensitive resin composition according to claim 1;
a step of photo-curing a part of the layer of the photosensitive resin composition; and
a step of removing at least a part of an uncured area of the layer of the photosensitive resin composition to form a cured product pattern.

20. A method for producing a laminate, the method comprising:
a step of disposing a layer of the photosensitive resin composition on a base material by using the photosensitive element according to claim 18;
a step of photo-curing a part of the layer of the photosensitive resin composition; and
a step of removing at least a part of an uncured area of the layer of the photosensitive resin composition to form a cured product pattern.

21. The photosensitive resin composition according to claim 14, which is in a film form.

22. A photosensitive element comprising: a support; and a photosensitive resin layer disposed on the support, wherein
the photosensitive resin layer is a layer of the photosensitive resin composition according to claim 14.

23. A method for producing a laminate, the method comprising:
a step of disposing a layer of the photosensitive resin composition on a base material by using the photosensitive resin composition according to claim 14;
a step of photo-curing a part of the layer of the photosensitive resin composition; and
a step of removing at least a part of an uncured area of the layer of the photosensitive resin composition to form a cured product pattern.

24. A method for producing a laminate, the method comprising:
a step of disposing a layer of the photosensitive resin composition on a base material by using the photosensitive element according to claim 22;
a step of photo-curing a part of the layer of the photosensitive resin composition; and
a step of removing at least a part of an uncured area of the layer of the photosensitive resin composition to form a cured product pattern.
